(19) United States
(12) Patent Application Publication
(10) Pub. No.: US 2026/0190332 A1
(43) Pub. Date: Jul. 2, 2026

(54) SEMICONDUCTOR DEVICES AND METHOD OF MANUFACTURING THE SAME

(71) Applicant: Samsung Electronics Co., Ltd., Suwon-si (KR)

(72) Inventors: Heejae Chae, Suwon-si (KR); Donghyung Kim, Suwon-si (KR); Yongkwan Kim, Suwon-si (KR); Huijung Kim, Suwon-si (KR); Huiyeong Park, Suwon-si (KR); Sangho Lee, Suwon-si (KR); Hyunjin Lee, Suwon-si (KR)

(21) Appl. No.: 19/385,206

(22) Filed: Nov. 11, 2025

(30) Foreign Application Priority Data
Dec. 30, 2024 (KR) 10-2024-0199945

(51) Int. Cl. H10B 12/00

(52) U.S. Cl. CPC H10B 12/50; H10B 12/34; H10B 12/482; H10B 12/488; H10B 12/053; H10B 12/09

(57) ABSTRACT

A semiconductor device may include a substrate having a cell array region, a peripheral circuit region, and a connection region; a cell element separation pattern defining a cell active region on the cell array region; a peripheral element separation pattern defining a peripheral active region on the peripheral circuit region; a separation insulating pattern between the cell element separation pattern and the peripheral element separation pattern on the connection region; and a cell gate structure. A lower surface of the separation insulating pattern may include a first lower region adjacent to the peripheral circuit region and on a first level, a second lower region adjacent to the cell array region and on a second level that is higher than the first level relative to an upper surface of the substrate, and a first step portion between the first lower region and the second lower region.

### CROSS-REFERENCE TO RELATED APPLICATION(S)

This application claims benefit of priority to Korean Patent Application No. 10-2024-0199945 filed on Dec. 30, 2024, in the Korean Intellectual Property Office, the disclosure of which is incorporated herein by reference in its entirety.

### TECHNICAL FIELD

The present disclosure relates to semiconductor devices and methods of manufacturing the same.

### BACKGROUND

Semiconductor devices are important elements in the electronic industry, due to characteristics such as miniaturization, multifunctionality and/or low manufacturing costs. Information storage devices are types of semiconductor devices that may be used to store logical data. With the development of the electronic industry, information storage devices have become more integrated. Various research has been conducted to improve the reliability of semiconductor devices, including information storage devices.

### SUMMARY

Embodiments of the present disclosure provide a semiconductor device having improved reliability and a method for manufacturing the semiconductor device.

However, embodiments of the present disclosure are not limited to the above, and may be variously expanded without departing from the present disclosure.

A semiconductor device according to example embodiments of the present disclosure may include: a substrate having a cell array region, a peripheral circuit region, and a connection region between the cell array region and the peripheral circuit region; a cell element separation pattern defining a cell active region on the cell array region, on the substrate; a peripheral element separation pattern defining a peripheral active region on the peripheral circuit region, on the substrate; a separation insulating pattern between the cell element separation pattern and the peripheral element separation pattern on the connection region of the substrate; and a cell gate structure intersecting the cell active region and extending into the separation insulating pattern, and a lower surface of the separation insulating pattern may include a first lower region adjacent to the peripheral circuit region and on a first level, a second lower region adjacent to the cell array region and on a second level that is higher than the first level relative to an upper surface of the substrate, and a first step portion between the first lower region and the second lower region.

A semiconductor device according to example embodiments of the present disclosure may include: a substrate having a cell array region, a peripheral circuit region, and a connection region between the cell array region and the peripheral circuit region; a cell element separation pattern defining a cell active region on the cell array region, on the substrate; a peripheral element separation pattern defining a peripheral active region on the peripheral circuit region, on the substrate; a separation insulating pattern between the cell element separation pattern and the peripheral element separation pattern on the connection region of the substrate; and a cell gate structure intersecting the cell active region and extending into the separation insulating pattern, and a lower surface of the separation insulating pattern may include a first lower region on a first level, a second lower region on a second level that is higher than the first level relative to an upper surface of the substrate, and a first step portion between the first lower region and the second lower region, the first lower region may have a non-planar surface having a rounded profile in cross-section, and the second lower region may have a surface that is inclined toward the first lower region.

A semiconductor device according to example embodiments of the present disclosure may include: a substrate having a cell array region, a peripheral circuit region, and a connection region between the cell array region and the peripheral circuit region; a cell element separation pattern defining cell active regions on the cell array region, on the substrate; a peripheral element separation pattern defining peripheral active regions on the peripheral circuit region, on the substrate; a separation insulating pattern on the connection region on the substrate; a cell gate structure intersecting the cell active regions and extending into a portion of the separation insulating pattern; a bit line structure intersecting the cell active regions and the cell gate structure; and a cell gate contact plug connected to the cell gate structure on the connection region and overlapping the separation insulating pattern in a direction perpendicular to an upper surface of the substrate, and the cell element separation pattern may include a first cell separation pattern having a first depth and a second cell separation pattern having a second depth that is greater than the first depth relative to the upper surface of the substrate, the separation insulating pattern may have a lower surface on a lower level than the cell element separation pattern and the peripheral element separation pattern relative to the upper surface of the substrate, and the lower surface of the separation insulating pattern may include a first lower region adjacent to the peripheral circuit region and on a first level, a second lower region adjacent to the cell array region and on a second level that is higher than the first level relative to the upper surface of the substrate, and a step portion between the first lower region and the second lower region.

According to example embodiments of the present disclosure, a method for manufacturing a semiconductor device may include: preparing a substrate having a cell array region, a peripheral circuit region, and a connection region between the cell array region and the peripheral circuit region; forming peripheral trenches in the peripheral circuit region and forming a first auxiliary connection trench in the connection region adjacent to the peripheral circuit region; forming a second auxiliary connection trench extending from the first auxiliary connection trench in the connection region; and forming cell trenches in the cell array region and forming a connection trench in the connection region adjacent to the cell array region.

According to an example embodiment, a method for manufacturing a semiconductor device may further include: forming a first sacrificial layer exposing an upper surface of a central region of the connection region surrounded by a peripheral region of the connection region; and forming a first mask layer on the upper surface of the central region of the connection region and the first sacrificial layer.

According to an example embodiment, the forming the peripheral trenches and the first auxiliary connection trench may include: forming a first mask pattern exposing the peripheral circuit region and portions of the connection region extending from the peripheral circuit region, on the first sacrificial layer; and performing a first etching process on the substrate using the first mask pattern.

According to an example embodiment, the forming the second auxiliary connection trench connected to the first auxiliary connection trench may include: forming the first mask layer extending from the cell array region and on a portion of the central region of the connection region, and a first sacrificial liner on the peripheral trench and the first auxiliary connection trench; forming a second sacrificial layer on the first sacrificial liner so that an upper surface of the first sacrificial liner formed on the first mask layer is exposed; and removing the first sacrificial liner and the first mask pattern exposed from the second sacrificial layer to expose the first sacrificial layer.

According to an example embodiment, the forming the cell trenches and the connection trench may include: removing the first sacrificial layer and the second sacrificial layer, and performing a second etching process on the substrate using the first sacrificial liner.

According to an example embodiment, the first sacrificial liner may be conformally formed according to surface profiles of the first mask layer, the peripheral trench, and the first auxiliary connection trench.

According to an example embodiment, the method of manufacturing a semiconductor device may further include: forming cell mask patterns on the cell array region, and forming peripheral mask patterns on the peripheral circuit region, and each of the cell mask patterns may include a first cell mask pattern and a second cell mask pattern spaced apart from the first cell mask pattern by a first size, and a space between the cell mask patterns may have a second size greater than the first size.

According to an example embodiment, the peripheral mask patterns may have a third size greater than the second size.

According to an example embodiment, the forming cell trenches within the cell array region may include: forming a first cell trench between the first cell mask pattern and the second cell mask pattern, and forming a second cell trench between the cell mask patterns.

According to an example embodiment, a width of the peripheral trench in the first direction may be smaller than a width of the first auxiliary connection trench in the first direction.

In example embodiments of the present disclosure, a semiconductor device may include a separation insulating pattern in a connection region between a peripheral circuit region and a cell array region on a substrate, and a lower surface of the separation insulating pattern may include a first lower region adjacent to the peripheral circuit region and a second lower region adjacent to the cell array region and on a higher level than the first lower region, relative to an upper surface of the substrate. In a manufacturing process of a semiconductor device, a portion of a separation trench for forming a separation insulating pattern in a connection region may be formed using a same process as or simultaneously with a peripheral trench for forming a peripheral element separation pattern in the peripheral circuit region, and a remaining portion of the separation trench may be formed using a same process as or simultaneously with cell trenches for the cell element separation pattern in the cell array region. Accordingly, problems that may occur in the process of forming a mask pattern in the peripheral circuit region (e.g., occurrence of a defect due to a peripheral mask pattern or a phenomenon of a mask pattern breaking) in the process of forming a separation insulating pattern in a connection region between a cell array region and a peripheral circuit region may be improved, thereby providing a semiconductor device having improved reliability.

However, advantages and effects of the present disclosure are not limited to the foregoing and may be variously expanded without departing from the scope of the present disclosure.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic plan view of a semiconductor device according to example embodiments of the present disclosure;

FIG. 2A is cross-sectional views taken along line I-I′ and line II-II′ of the semiconductor device of FIG. 1 according to an example embodiment;

FIG. 2B is a cross-sectional view taken along line III-III′ of the semiconductor device of FIG. 1 according to an example embodiment;

FIG. 2C is a cross-sectional view taken along line IV-IV′ of the semiconductor device of FIG. 1 according to an example embodiment;

FIG. 3A is an enlarged view of region “A” according to an example embodiment of the semiconductor device shown in FIG. 2B;

FIG. 3B is an enlarged view of region “A” according to another embodiment of the semiconductor device shown in FIG. 2B;

FIGS. 4A, 4B, 4C, 4D, 4E, 4F, 4G, 4H, 4I, 4J, 4K, 4L, 4M, 4N, 4O, and 4P are views illustrating a method of manufacturing a semiconductor device according to an example embodiment of the present disclosure; and

FIGS. 5A, 5B, 5C, 5D, 5E, 5F, 5G, and 5H are diagrams illustrating a method of manufacturing a semiconductor device according to another example embodiment of the present disclosure.

### DETAILED DESCRIPTION

Hereinafter, example embodiments of the present disclosure will be described with reference to the accompanying drawings. The same reference numerals are used for the same components in the drawing, and redundant descriptions for the same components are omitted. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly” on, or “in direct contact” or “directly connected,” no intervening components or layers are present.

Components or layers described with reference to “overlap” in a particular direction may be at least partially obstructed by one another when viewed along a line extending in the particular direction or in a plane perpendicular to the particular direction. Spatially relative terms such as “above,” “upper,” “upper portion,” “upper surface,” “below,” “lower,” “lower portion,” “lower surface,” “side surface,” and the like may be denoted by reference numerals and refer to the drawings, except where otherwise indicated. It will be understood that such spatially relative terms are intended to encompass different orientations of the device in use or operation in addition to the orientation depicted in the figures.

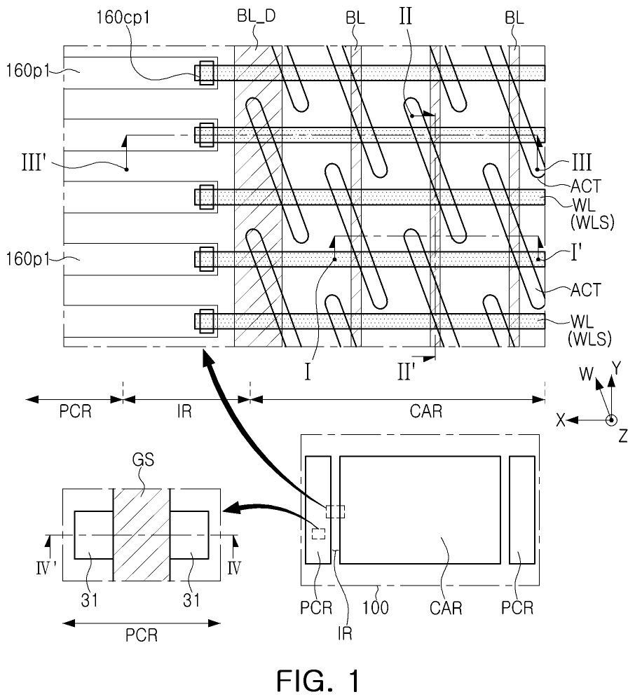

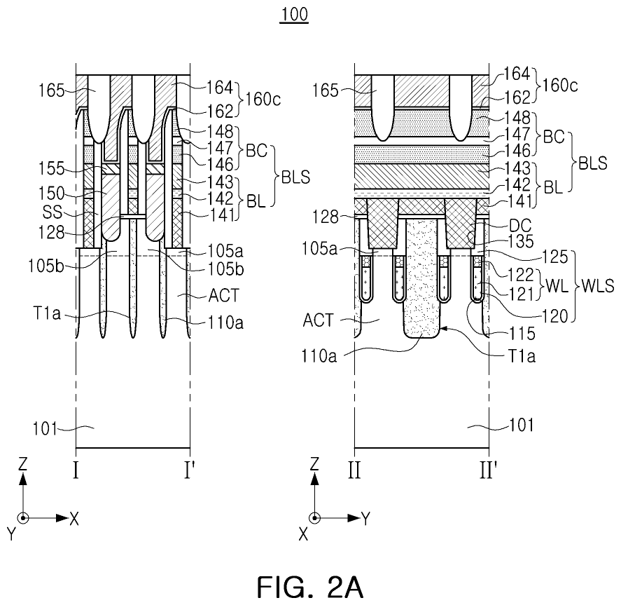

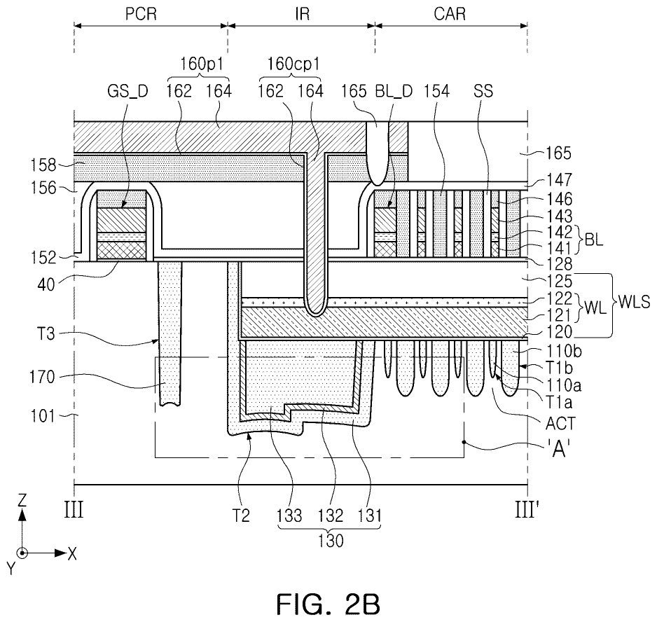

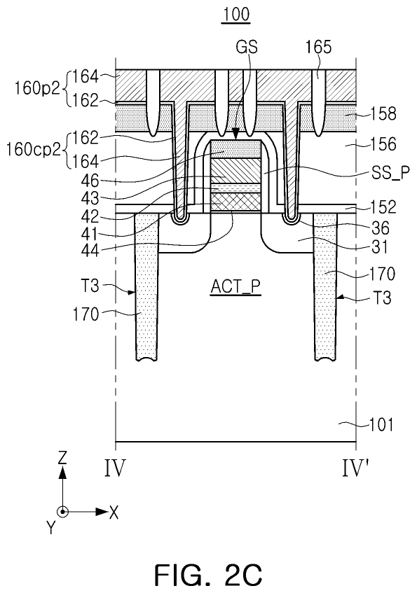

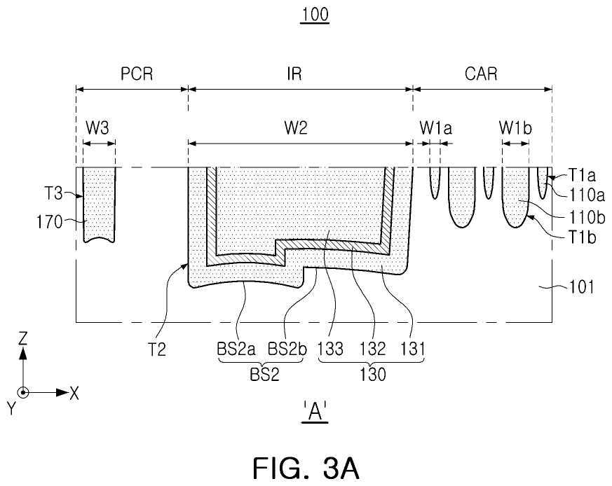

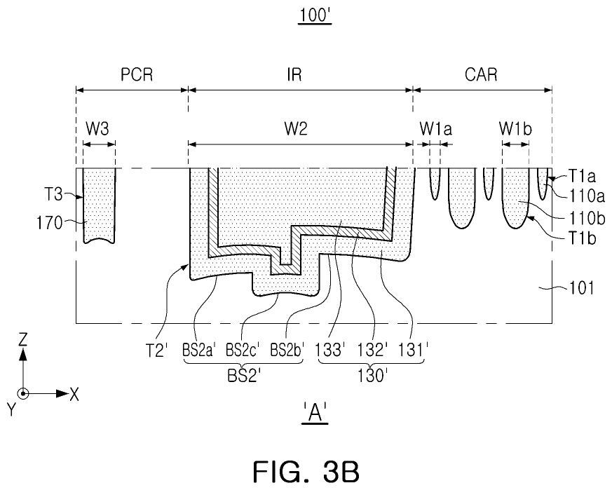

FIG. 1 is a schematic plan view of a semiconductor device according to example embodiments of the present disclosure. FIG. 2A is cross-sectional views taken along line I-I′ and line II-II′ of the semiconductor device of FIG. 1 according to an example embodiment. FIG. 2B is a cross-sectional view taken along line III-III′ of the semiconductor device of FIG. 1 according to an example embodiment. FIG. 2C is a cross-sectional view taken along line IV-IV′ of the semiconductor device of FIG. 1 according to an example embodiment. FIG. 3A is an enlarged view of region “A” according to an example embodiment of the semiconductor device illustrated in FIG. 2B.

Referring to FIG. 1, a semiconductor device 100 may include a cell array region CAR, a peripheral circuit region PCR for driving the cell array region CAR, and a connection region IR between the cell array region CAR and the peripheral circuit region PCR. In this specification, the regions CAR, PCR and IR may be defined and described in a substrate 101. The cell array region CAR may be a region in which memory cells are disposed. The peripheral circuit region PCR may be arranged around the cell array region CAR. The peripheral circuit region PCR may be a region in which word line drivers, sense amplifiers, row and column decoders, and control circuits are disposed. The connection region IR may be a region for electrically connecting the cell array region CAR and the peripheral circuit region PCR to each other. For example, in the connection region IR, a word line WL may be connected to a gate contact plug 160cp1, and the gate contact plug 160cp1 may be connected to a second upper conductive pattern 160p1.

Referring to FIGS. 1, 2A, 2B and 2C, the semiconductor device 100 may include a substrate 101 including cell active regions ACT, cell element separation patterns 110a and 110b defining the cell active regions ACT within the substrate 101, a cell gate structure WLS embedded and extending within the substrate 101 and including a word line WL, and a bit line structure BLS extending by intersecting the cell gate structure WLS on the substrate 101 and including a bit line BL. The cell active regions ACT, the cell gate structure WLS, and the bit line structure BLS may be disposed in the cell array region CAR.

The semiconductor device 100 may further include a lower conductive pattern 150 on the cell active region ACT, a first upper conductive pattern 160c on the lower conductive pattern 150, a gate contact plug 160cp1 connected to a word line WL in a connection region IR, a second upper conductive pattern 160p1 on the gate contact plug 160cp1, a peripheral contact plug 160cp2 connected to a peripheral source/drain region 31 in a peripheral circuit region PCR, a third upper conductive pattern 160p2 on the peripheral contact plug 160cp2, and an insulating pattern 165 penetrating through the upper conductive patterns 160c, 160p1 and 160p2.

The semiconductor device 100 may further include a peripheral transistor, an insulating liner 152, and interlayer insulating layers 156 and 158 disposed on the substrate 101 in the peripheral circuit region PCR, and the peripheral transistor may include a peripheral gate dielectric layer 44, peripheral gate electrodes 41, 42 and 43, and peripheral source/drain regions 31.

The semiconductor device 100 may include, for example, a cell array of a Dynamic Random Access Memory (DRAM). For example, the bit line BL may be connected to a first impurity region 105a of the cell active region ACT, and a second impurity region 105b of the cell active region ACT may be electrically connected to a capacitor structure on the first upper conductive pattern 160c through the lower and upper conductive patterns 150 and 160c. Although not shown, the capacitor structure may include, for example, a lower electrode, a capacitor dielectric layer, and an upper electrode, and the structure thereof is not particularly limited.

The substrate 101 may include a semiconductor material, such as a group IV semiconductor, a group III-V compound semiconductor, or a group II-VI compound semiconductor. For example, the group IV semiconductor may include silicon, germanium, or silicon-germanium. The substrate 101 may further include impurities. The substrate 101 may be a silicon substrate, a silicon-on-insulator (SOI) substrate, a germanium substrate, a germanium-on-insulator (GOI) substrate, a silicon-germanium substrate, or a substrate including an epitaxial layer.

The cell active regions ACT may be defined within the substrate 101 by cell element separation patterns 110a and 110b. The cell active region ACT may be in the form of a bar, and may be disposed in an island shape extending in one direction, for example, in a diagonal (W-direction) relative to first and second horizontal directions (X-and Y-directions) within the substrate 101. The diagonal direction (W-direction) may be an inclined direction with respect to an extension direction of the word lines WL (X-direction) and the bit lines BL (Y-direction). The cell active regions ACT may be arranged to be parallel to each other, but may be arranged such that an end of one cell active region ACT is adjacent to the center or central portion of another cell active region ACT adjacent thereto.

The cell active region ACT may have first and second impurity regions 105a and 105b of a predetermined depth from an upper surface of the substrate 101. The first and second impurity regions 105a and 105b may be spaced apart from each other. The first and second impurity regions 105a and 105b may be provided as source/drain regions of a transistor configured by a word line WL. For example, a drain region may be formed between two word lines WL intersecting one cell active region ACT, and a source region may be formed outside each of the two word lines WL. The source region and the drain region may be formed by the first and second impurity regions 105a and 105b by doping or ion implantation of substantially the same impurities, and may be referred to interchangeably (or may be referred to as source/drain regions) depending on the circuit configuration of the transistor to be finally formed. The impurities may include dopants having a conductivity type opposite to that of the substrate 101. In example embodiments, depths of the first and second impurity regions 105a and 105b in the source region and the drain region may be different from each other.

The cell element separation patterns 110a and 110b may be formed by a shallow trench isolation (STI) process. The cell element separation patterns 110a and 110b may surround the cell active regions ACT and electrically isolate them from each other. The term “surround” or “cover” or “fill” as may be used herein may not require completely surrounding or covering or filling the described elements or layers, but may, for example, refer to partially surrounding or covering or filling the described elements or layers, for example, with voids, spaces, or other discontinuities throughout. The cell element separation patterns 110a and 110b may be formed of an insulating material, and may be, for example, silicon oxide, silicon nitride, or combinations thereof. The cell element separation patterns 110a and 110b may include a plurality of regions having depths of different lower ends depending on a width of a trench in which the substrate 101 is etched.

The cell element separation patterns 110a and 110b may include a first cell element separation pattern 110a filling a first cell trench T1a and a second cell element separation pattern 110b alternately arranged with the first cell element separation pattern 110a and filling a second cell trench T1b. In one example, the first cell element separation pattern 110a may extend in the diagonal direction (W-direction) between the cell active regions ACT. In one example, a horizontal width W1b of the second cell element separation pattern 110b in a first direction (X-direction) may be greater than a horizontal width W1a of the first cell element separation pattern 110a in the first direction (X-direction). The second cell element separation pattern 110b may be disposed between cell active regions ACT adjacent to each other in the diagonal direction (W-direction), and, in the illustrated example, the second cell element separation pattern 110b may be disposed between four adjacent cell active regions ACT.

Upper surfaces of the first and second cell element separation patterns 110a and 110b may be coplanar with the substrate 101.

The first and second cell element separation patterns 110a and 110b may include lower surfaces disposed on a lower level than a lower surface of the cell gate structure WLS. The term “level” as used herein may refer to a distance of an element or layer (or surface thereof) from or relative to a reference element or layer (or surface thereof), for example, a substrate. Elements at a same level may have substantially coplanar surfaces. In one example, the first cell element separation pattern 110a may have a lower surface disposed on a higher level than a lower surface of the second cell element separation pattern 110b. A lower region of the first cell element separation pattern 110a and a lower region of the second cell element separation pattern 110b may be in contact with a side surface of the cell gate structure WLS.

A length or depth from the upper surface to the lower surface of the first cell element separation pattern 110a may be smaller than a length or depth from the upper surface to the lower surface of the second cell element separation pattern 110b. A vertical level of the lower surface of the first cell element separation pattern 110a may be higher than a vertical level of the lower surface of the second cell element separation pattern 110b, relative to an upper surface of the substrate.

The upper surfaces of the first and second cell element separation patterns 110a and 110b may be coplanar with the upper surface of the substrate 101. In one example, the first cell element separation pattern 110a may include the same insulating material as the second cell element separation pattern 110b. For example, the first and second cell element separation patterns 110a and 110b may include silicon oxide, silicon nitride, silicon oxynitride, or combinations thereof. In an example embodiment, the first and second cell element separation patterns 110a and 110b may include silicon oxide.

The semiconductor device 100 may further include peripheral element separation patterns 170 defining the peripheral active region ACT_P on the peripheral circuit region PCR and a separation insulating pattern 130 dividing the cell active region ACT and the peripheral active region ACT_P on the connection region IR disposed between the peripheral circuit region PCR and the cell array region CAR.

The peripheral element separation pattern 170 may fill a peripheral trench T3. The peripheral element separation pattern 170 may include the same insulating material as the first and second cell element separation patterns 110a and 110b. For example, the peripheral element separation pattern 170 may include silicon oxide. A horizontal width W3 of the peripheral element separation pattern 170 in the first direction (X-direction) may be greater than a horizontal width W1b of the second cell element separation pattern 110b in the first direction (X-direction). The peripheral element separation pattern 170 may extend in the second direction (Y-direction), and may have a lower surface disposed on a lower level than lower surfaces of the first and second cell element separation patterns 110a and 110b, relative to an upper surface of the substrate 101.

The separation insulating pattern 130 may fill a connection trench T2. The separation insulating pattern 130 may include a first insulation layer 131, a second insulation layer 132, and a third insulation layer 133 sequentially stacked. The first insulation layer 131 and the third insulation layer 133 may include silicon oxide, and the second insulation layer 132 may include silicon nitride. The first insulation layer 131, the second insulation layer 132 and the third insulation layer 133 may be sequentially disposed conformally according to a surface profile of the connection trench T2. The third insulating layer 133 may fill a space in which the first and second insulating layers 131 and 132 do not fill the trench. That is, the first and second insulating layers 131 and 132 may be conformally formed or extend along the surface profile of the connection trench T2, while the third insulating layer 133 may fill a remainder of the trench T2.

A dummy gate structure GS_D may be disposed in the peripheral circuit region PCR adjacent to the connection region IR, but the present disclosure is not limited thereto.

A horizontal width W2 of the separation insulating pattern 130 in the first direction (X-direction) may be greater than the horizontal width W3 of the peripheral element separation pattern 170 in the first direction (X-direction). In one example, the horizontal width W2 of the separation insulating pattern 130 in the first direction (X-direction) may correspond to a horizontal width of the connection region IR in the first direction (X-direction).

Referring to FIGS. 2B and 3A, a lower surface or floor BS2 of the separation insulating pattern 130 may be disposed on a lower level than the lower surfaces of the first and second cell element separation patterns 110a and 110b and a lower surface of the peripheral element separation pattern 170, relative to an upper surface of the substrate 101. For example, a lower surface of the first insulating layer 131 may be disposed on a lower level than the lower surfaces of the first and second cell element separation patterns 110a and 110b and the lower surface of the peripheral element separation pattern 170. However, the present disclosure is not limited thereto. For example, the lower surface BS2 of the separation insulating pattern 130 may be disposed on substantially the same level as the lower surfaces of the first and second cell element separation patterns 110a and 110b and/or the lower surface of the peripheral element separation pattern 170.

The lower surface BS2 of the separation insulating pattern 130 may include a first lower region BS2a adjacent to the peripheral circuit region PCR and a second lower region BS2b adjacent to the cell array region CAR. The first lower region BS2a may be disposed on a lower level than that of the second lower region BS2b, and a first step portion may be formed between the first lower region BS2a and the second lower region BS2b which are disposed on different levels. A level of the first lower region BS2a may refer to the lowest level in the first lower region BS2a, in a vertical (shown as Z-) direction. A level of the second lower region BS2b may mean the lowest level of the second lower region BS2b in the vertical direction. The first step portion may be formed at a difference between the level of the first lower region BS2a and the level of the second lower region BS2b.

In one example, the first lower region BS2a may be adjacent to the peripheral element separation pattern 170, and the second lower region BS2b may be adjacent to the first and second cell element separation patterns 110a and 110b. In one example, the connection trench T2 may be formed so that the lower surface BS2 of the separation insulating pattern 130 may have the first lower region BS2a and the second lower region BS2b.

The first lower region BS2a may have a non-flat or non-planar surface, and the non-flat surface may have a rounded profile. The first lower region BS2a may have a convex surface profile toward the upper surface of the substrate 101. The second lower region BS2b may be disposed on a higher level than that of the first lower region BS2a, but may have a surface inclined downward toward the cell array region CAR. The second lower region BS2b may have a surface inclined upward toward the first lower region BS2a. The second lower region BS2b may have a surface whose level increases closer to the first lower region BS2a.

The cell gate structures WLS may be disposed within gate trenches 115 extending within the substrate 101. Each of the cell gate structures WLS may include a gate dielectric layer 120, a word line WL, and a gate capping layer 125. In this specification, ‘a gate (120, WL)’ may be referred to as a structure including the gate dielectric layer 120 and the word line WL, the word line WL may be referred to as a ‘gate electrode’, and the cell gate structure WLS may be referred to as a ‘word line structure’.

The word line WL may be disposed to extend in a first direction (X-direction) by intersecting the cell active region ACT. For example, a pair of word lines WL adjacent to each other may be disposed to intersect one cell active region ACT. The word line WL may form a gate of a buried channel array transistor (BCAT), but the present disclosure is not limited thereto. In example embodiments, the word lines WL may also have a form of being disposed on an upper portion of the substrate 101. The word line WL may be disposed at a predetermined thickness on a lower portion of the gate trench 115. An upper surface of the word line WL may be disposed on a level lower than that of the upper surface of the substrate 101. In this specification, a high level and a low level of the term “level” used may be defined based on or relative to a substantially flat upper surface of the substrate 101.

The word line WL may include at least one of a conductive material, for example, polycrystalline silicon (Si), titanium (Ti), titanium nitride (TiN), tantalum (Ta), tantalum nitride (TaN), tungsten (W), tungsten nitride (WN), and aluminum (Al). For example, the word line WL may include a lower pattern 121 and an upper pattern 122 formed of different materials.

For example, the lower pattern 121 may include at least one of tungsten (W), titanium (Ti), tantalum (Ta), tungsten nitride (WN), titanium nitride (TiN), and tantalum nitride (TaN). For example, the upper pattern 122 may be a semiconductor pattern including polysilicon doped with P-type or N-type impurities, and the lower pattern 121 may be a metal pattern including at least one of a metal and a metal nitride. A thickness of the lower pattern 121 may be thicker than a thickness of the upper pattern 122. Each of the lower pattern 121 and the upper pattern 122 may extend in the first direction (X-direction).

The gate dielectric layer 120 may be disposed on a lower surface and inner surfaces of the gate trench 115. The gate dielectric layer 120 may conformally cover an inner wall of the gate trench 115. The gate dielectric layer 120 may include at least one of silicon oxide, silicon nitride, and silicon oxynitride. The gate dielectric layer 120 may be, for example, a silicon oxide film or an insulating film having a high dielectric constant. In example embodiments, the gate dielectric layer 120 may be a layer formed by oxidizing the cell active region ACT or a layer formed by deposition.

The gate capping layer 125 may be disposed to fill the gate trench 115 in an upper portion of the word line WL. An upper surface of the gate capping layer 125 may be disposed on substantially the same level as or coplanar with the upper surface of the substrate 101. The gate capping layer 125 may be formed of an insulating material, for example, silicon nitride.

The bit line structure BLS may extend in one direction, for example, in the second direction (Y-direction), intersecting or perpendicular to the word line WL. The bit line structure BLS may include a bit line BL and a bit line capping pattern BC on the bit line BL. The bit line structure BLS may be disposed on a cell array region CAR, and a dummy bit line structure BL_D having a greater width in the first direction (X-direction) than the bit line structure BLS may be disposed between the connection region IR and the cell array region CAR. The dummy bit line structure BL_D may have a structure similar to the bit line structure BLS, except that the dummy bit line structure BL_D has a greater width.

The bit line BL may include a first conductive pattern 141, a second conductive pattern 142, and a third conductive pattern 143, which are sequentially stacked. The bit line capping pattern BC may be disposed on the third conductive pattern 143. A buffer insulating layer 128 may be disposed between the first conductive pattern 141 and the substrate 101, and a portion of the first conductive pattern 141 (hereinafter, a bit line contact pattern DC) may be in contact with the first impurity region 105a of the cell active region ACT. The bit line BL may be electrically connected to the first impurity region 105a through the bit line contact pattern DC. A lower surface of the bit line contact pattern DC may be disposed on a lower level than that of the upper surface of the substrate 101, and may be disposed on a higher level than that of the upper surface of the word line WL. In an example embodiment, the bit line contact pattern DC may be locally disposed within a bit line contact hole 135 formed within the substrate 101 and exposing the first impurity region 105a.

The first conductive pattern 141 may include a semiconductor material such as polycrystalline silicon. The first conductive pattern 141 may be in direct contact with the first impurity region 105a. The second conductive pattern 142 may include a metal-semiconductor compound. The metal-semiconductor compound may be, for example, a layer in which a portion of the first conductive pattern 141 is silicided. For example, the metal-semiconductor compound may include cobalt silicide (CoSi), titanium silicide (TiSi), nickel silicide (NiSi), tungsten silicide (WSi), or other metal silicides. The third conductive pattern 143 may include a metal material such as titanium (Ti), tantalum (Ta), tungsten (W), and aluminum (Al). The number of conductive patterns forming the bit line BL, the type of material, and/or the stacking order may be variously changed depending on example embodiments.

The bit line capping pattern BC may include a first capping pattern 146, a second capping pattern 147, and a third capping pattern 148, which are sequentially stacked on a third conductive pattern 143. Each of the first to third capping patterns 146, 147 and 148 may include an insulating material, for example, a silicon nitride film. The first to third capping patterns 146, 147 and 148 may be formed of different materials, and even if the first to third capping patterns 146, 147 and 148 include the same material, boundaries thereof may be distinguished due to differences in physical properties. A thickness of the second capping pattern 147 may be smaller than a thickness of the first capping pattern 146 and a thickness of the third capping pattern 148, respectively. The number of capping patterns and/or the type of material included in the bit line capping pattern BC may be variously changed according to example embodiments.

Spacer structures SS may be disposed on both sidewalls of each of the bit line structures BLS and may extend in one direction, for example, in a second direction (Y-direction). The spacer structures SS may be disposed between the bit line structure BLS and the lower conductive pattern 150. The spacer structures SS may be disposed to extend along sidewalls of the bit line BL and sidewalls of the bit line capping pattern BC. A pair of spacer structures SS disposed on both sides of one bit line structure BLS may have an asymmetrical shape with respect to the bit line structure BLS. Each of the spacer structures SS may include a plurality of spacer layers and may further include an air spacer according to example embodiments.

The lower conductive pattern 150 may be connected to one region of the cell active region ACT, for example, the second impurity region 105b. The lower conductive pattern 150 may be disposed between the bit lines BL and between the word lines WL. The lower conductive pattern 150 may penetrate through the buffer insulating layer 128 and may be connected to the second impurity region 105b of the cell active region ACT. The lower conductive pattern 150 may be in direct contact with the second impurity region 105b. A lower surface of the lower conductive pattern 150 may be disposed on a level lower than that of the upper surface of the substrate 101, and may be disposed on a level higher than that of the lower surface of the bit line contact pattern DC. The lower conductive pattern 150 may be insulated from the bit line contact pattern DC by the spacer structure SS. The lower conductive pattern 150 may be formed of a conductive material, and may include, for example, at least one of polycrystalline silicon (Si), titanium (Ti), titanium nitride (TiN), tantalum (Ta), tantalum nitride (TaN), tungsten (W), tungsten nitride (WN), and aluminum (Al). In an example embodiment, a storage node contact 160 may include a plurality of layers.

A metal-semiconductor compound layer 155 may be disposed between the lower conductive pattern 150 and the first upper conductive pattern 160c. The metal-semiconductor compound layer 155 may be a layer obtained by siliciding a portion of the lower conductive pattern 150, for example, when the lower conductive pattern 150 includes a semiconductor material. The metal-semiconductor compound layer 155 may include, for example, cobalt silicide (CoSi), titanium silicide (TiSi), nickel silicide (NiSi), tungsten silicide (WSi), or other metal silicides. According to example embodiments, the metal-semiconductor compound layer 155 may be omitted.

The first upper conductive pattern 160c may be disposed on the lower conductive pattern 150 in the cell array region CAR. The first upper conductive pattern 160c may extend between the spacer structures SS to cover an upper surface of the metal-semiconductor compound layer 155. The second and third upper conductive patterns 160p1 and 160p2 may be disposed on the connection region IR and the peripheral circuit region PCR. The upper surfaces of each of the first to third upper conductive patterns 160c, 160p1 and 160p2 may be coplanar or disposed on substantially the same level. Each of the upper conductive patterns 160c, 160p1 and 160p2 may include a barrier layer 162 and a conductive layer 164. The barrier layer 162 may cover a lower surface and side surfaces of the conductive layer 164. The barrier layer 162 may include at least one of a metal nitride, for example, titanium nitride (TiN), tantalum nitride (TaN), and tungsten nitride (WN). The conductive layer 164 may include a conductive material, for example, at least one of polycrystalline silicon (Si), titanium (Ti), tantalum (Ta), tungsten (W), ruthenium (Ru), copper (Cu), molybdenum (Mo), platinum (Pt), nickel (Ni), cobalt (Co), aluminum (Al), titanium nitride (TiN), tantalum nitride (TaN), and tungsten nitride (WN).

The gate contact plug 160cp1 may be provided in the connection region IR. In the connection region IR, the gate contact plug 160cp1 may be connected to an end portion of a word line WL (or a word line structure WLS). In one example, the gate contact plug 160cp1 may be electrically connected to the word line WL of the cell gate structure WLS by penetrating through the first and second interlayer insulating layers 156 and 158, the insulating liner 152, and the gate capping layer 125 of the cell gate structure WLS in the connection region IR. The gate contact plug 160cp1 may be disposed between the dummy bit line structure BL_D and the dummy gate structure GS_D of the peripheral circuit region PCR. In one example, the gate contact plug 160cp1 may overlap the separation insulating pattern 130 in the vertical direction (Z-direction).

The end portion of the word line WL or an end portion of the cell gate structure WLS may be disposed on the separation insulating pattern 130 covering a sidewall of the cell active region ACT adjacent thereto. The end portion of the cell gate structure WLS may provide an end surface exposed in an extension direction of the cell gate structure WLS, i.e., in the first direction (X-direction). An end surface of the cell gate structure WLS may be a side surface of the gate dielectric layer 120. In the connection region IR, an end surface of the word line structure WLS may be disposed within the first insulating layer 131.

A lower surface LS of the cell gate structure WLS may be in contact with the first insulating layer 131, the second insulating layer 132 and the third insulating layer 133.

The gate contact plug 160cp1 may have a long axis in the first direction (X-direction) in a plane. For example, the gate contact plug 160cp1 may have a long bar shape in the first direction (X-direction). For example, the gate contact plug 160cp1 may have an elongated elliptical shape in the first direction (X-direction).

The gate contact plug 160cp1 may include a barrier layer 162 and a conductive layer 164. The gate contact plug 160cp1 may be connected to the second upper conductive pattern 160p1, and may be integral or unitary with the second upper conductive pattern 160p1. The gate contact plug 160cp1 may completely overlap the second upper conductive pattern 160p1 in a vertical direction (Z-direction).

The peripheral contact plug 160cp2 may penetrate through the first and second interlayer insulating layers 156 and 158 and the insulating liner 152 in the peripheral circuit region PCR and may be connected to the peripheral source/drain regions 31. A peripheral metal-semiconductor compound layer 36 may be disposed between the peripheral contact plug 160cp2 and the peripheral source/drain regions 31. The peripheral contact plug 160cp2 may be connected to the third upper conductive pattern 160p2, and may be integral with the third upper conductive pattern 160p2.

The insulating patterns 165 may be disposed to penetrate through the upper conductive patterns 160c, 160p1 and 160p2. The upper conductive patterns 160c, 160p1 and 160p2 may be separated into a plurality of piece by the insulating patterns 165. The insulating patterns 165 may include an insulating material, for example, at least one of silicon oxide, silicon nitride or silicon oxynitride.

A peripheral gate structure GS may be disposed on the peripheral active region ACT_P in the peripheral circuit region PCR. The peripheral gate structure GS may include a peripheral gate dielectric layer 44, peripheral gate electrodes 41, 42 and 43, and a peripheral gate capping layer 46, which are sequentially stacked. An insulating liner 152 may cover the peripheral gate structure GS. The peripheral active region ACT_P may be defined by the peripheral element separation pattern 170. The peripheral gate dielectric layer 44 may include silicon oxide, silicon nitride, or a high-κ material. The high-κ material may refer to a dielectric material having a higher dielectric constant than silicon oxide. The peripheral gate electrodes 41, 42 and 43 may be formed of a structure and material similar to that of the bit line BL, but may have a shape wider than that of the bit line BL.

In some examples described herein, the diagonal direction (W-direction) may be referred to as the first horizontal direction, the first direction (X-direction) may be referred to as the second horizontal direction, and the second direction (Y-direction) may be referred to as the third horizontal direction. However, in other examples, a “first” horizontal direction may be termed a “second” horizontal direction. More generally, the terms “first,” “second,” “third,” etc., may be used herein merely to distinguish one component, layer, direction, etc. from another.

FIG. 3B is an enlarged view of region “A” according to another embodiment of the semiconductor device illustrated in FIG. 2B.

Referring to FIG. 3B, a semiconductor device 100′ may include a separation insulating pattern 130′ filling a connection trench T2′. A lower surface BS2″ of the separation insulating pattern 130′ may include a first lower region BS2a′ adjacent to a peripheral circuit region PCR, a second lower region BS2b′ disposed on a higher level than that of the first lower region BS2a′ but disposed adjacently to the cell array region CAR, and a third lower region BS2c′ disposed between the first lower region BS2a′ and the second lower region BS2b′ but disposed on a lower level than that of the first lower region BS2a′, relative to an upper surface of the substrate 101. A first step portion may be formed between the first lower region BS2a′ and the third lower region BS2c′, and a second step portion may be formed between the second lower region BS2b′ and the third lower region BS2c′. In one example, the first step portion may be disposed on a lower level than that of the second step portion. The first step portion may be formed by a vertical level difference between the first lower region BS2a′ and the third lower region BS2c′, and the second step portion may be formed by a vertical level difference between the second lower region BS2b′ and the third lower region BS2c′.

The first lower region BS2a′ may be disposed on a lower level than that of the second lower region BS2b′, and may be disposed on a higher level than that of the third lower region BS2c′. The second lower region BS2b′ may be disposed on a higher level than that of the first lower region BS2a′ and the third lower region BS2c′. The third lower region BS2c′ may be disposed on a lower level than that of the first lower region BS2a′ and the second lower region BS2b′.

The third lower region BS2c′ may have a non-flat or non-planar surface, and the non-flat surface may have a rounded profile. The first lower region BS2a′ and the second lower region BS2b′ may have surfaces that are inclined upward toward the third lower region BS2c′. The first lower region BS2a′ and the second lower region BS2b′ may have surfaces in which a level thereof increases as the first lower region BS2a′ and the second lower region BS2b′ approach the third lower region BS2c′. The third lower region BS2c′ may have a convex surface profile toward the upper surface of the substrate 101.

The separation insulating pattern 130′ may include a first insulating layer 131′ conformally formed according to the surface profile of the connecting trench T2′, a second insulating layer 132′ conformally extending on the first insulating layer 131′, and a third insulating layer 133′ on the second insulating layer 132′ and filling the remainder of the trench T2′.

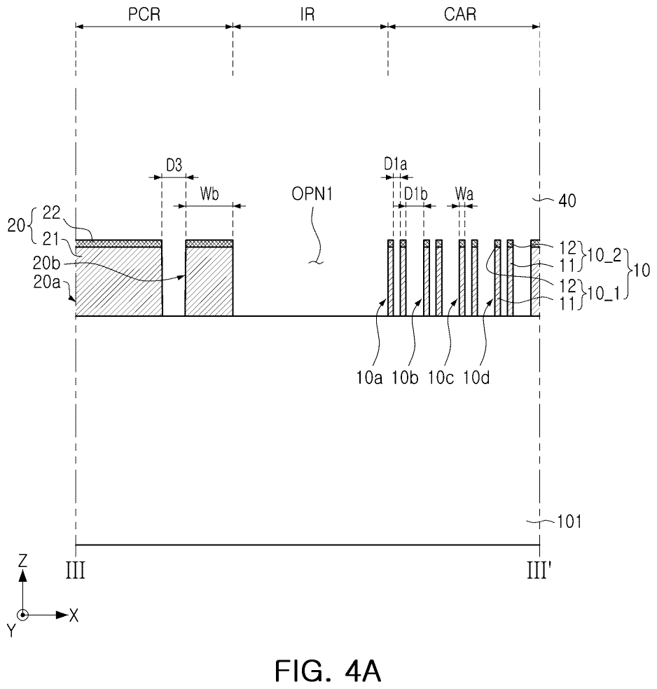

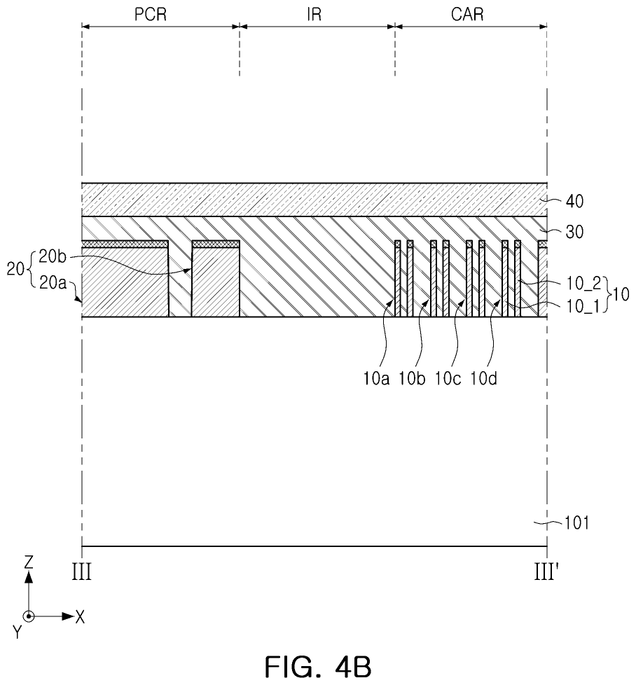

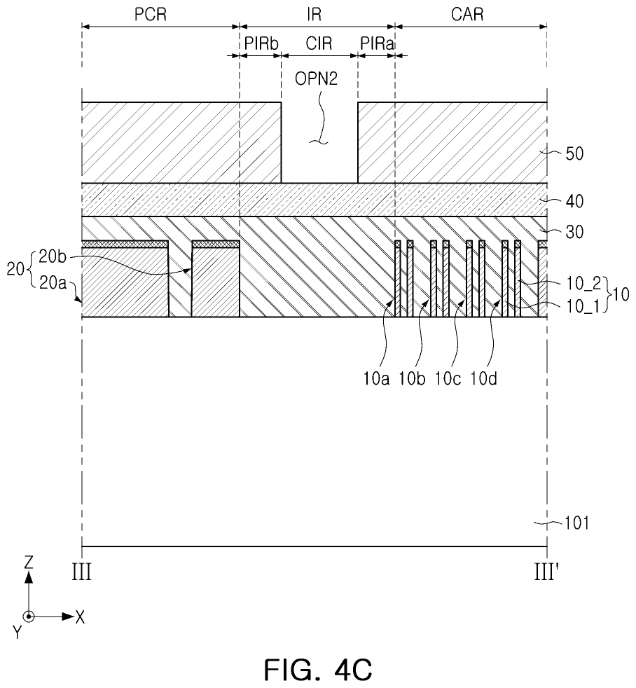

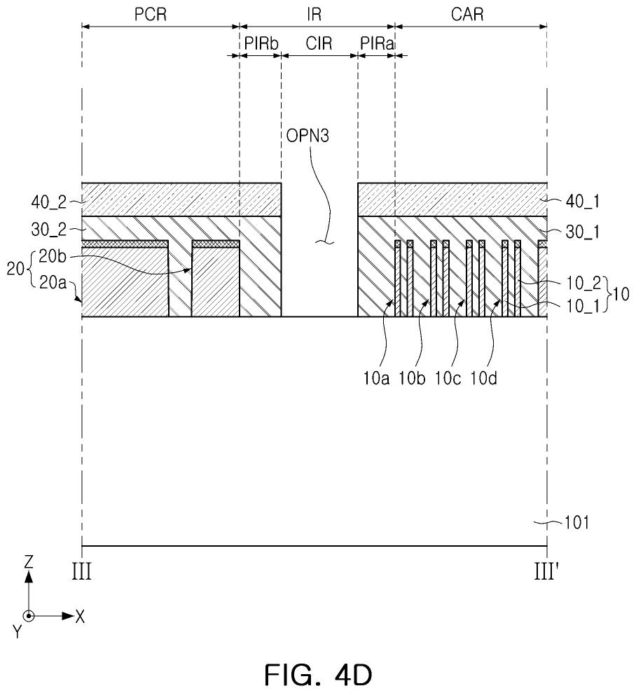

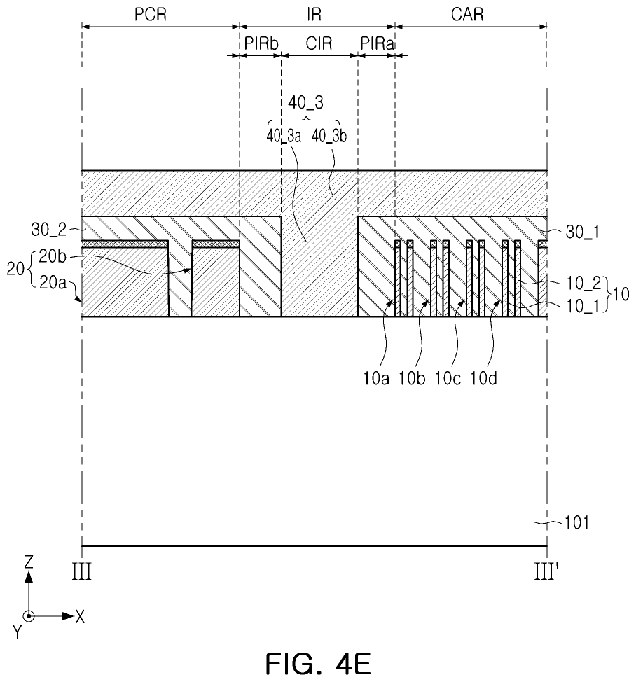

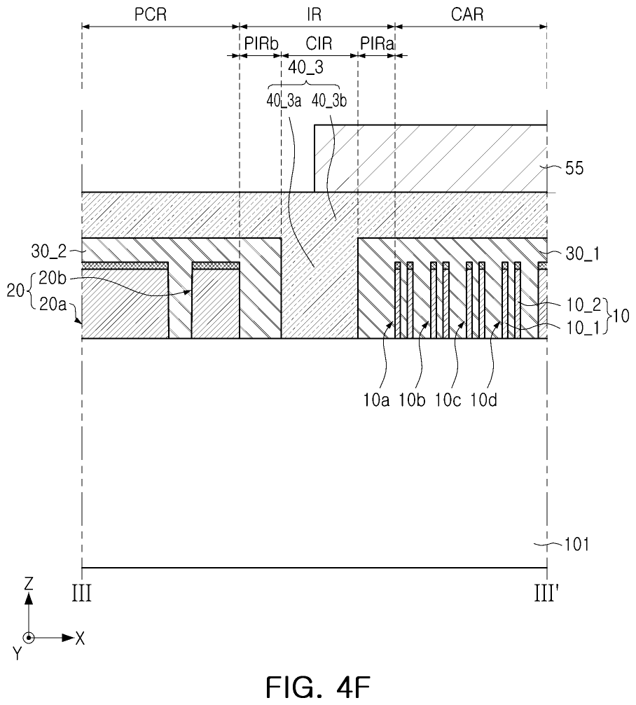

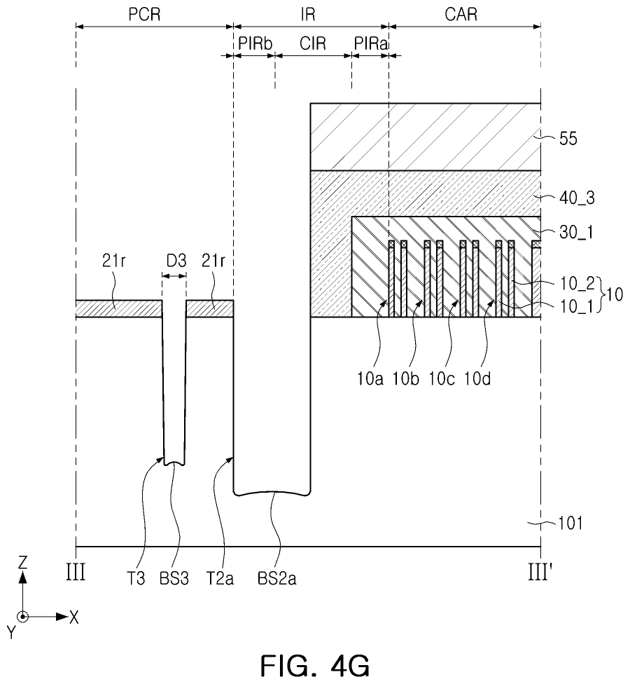

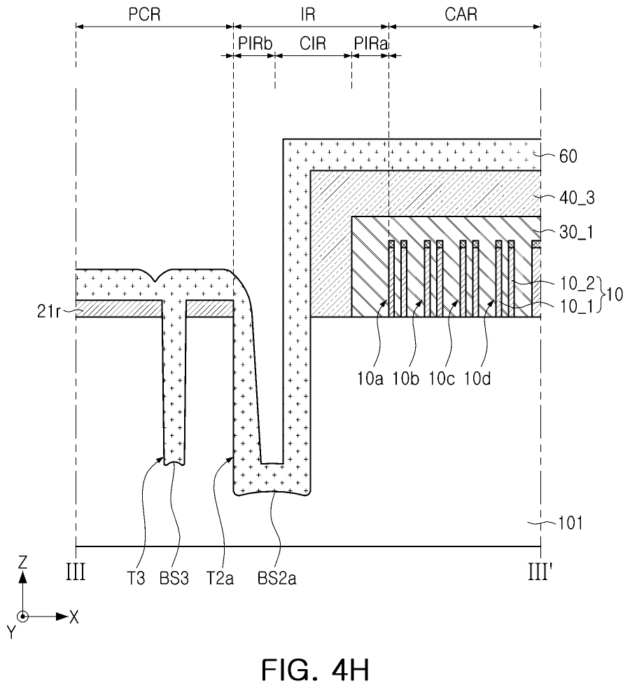

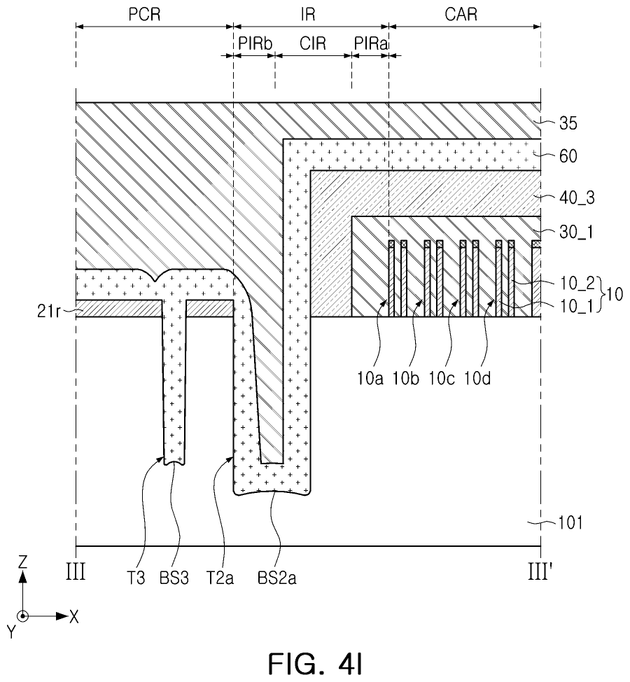

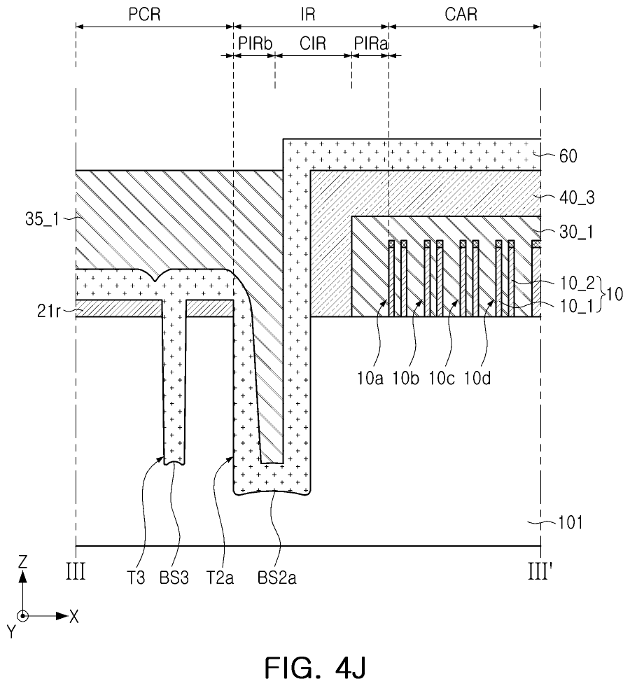

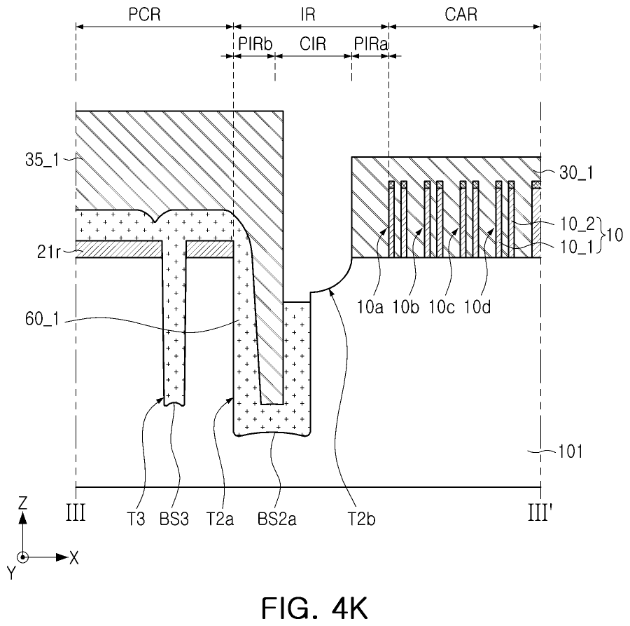

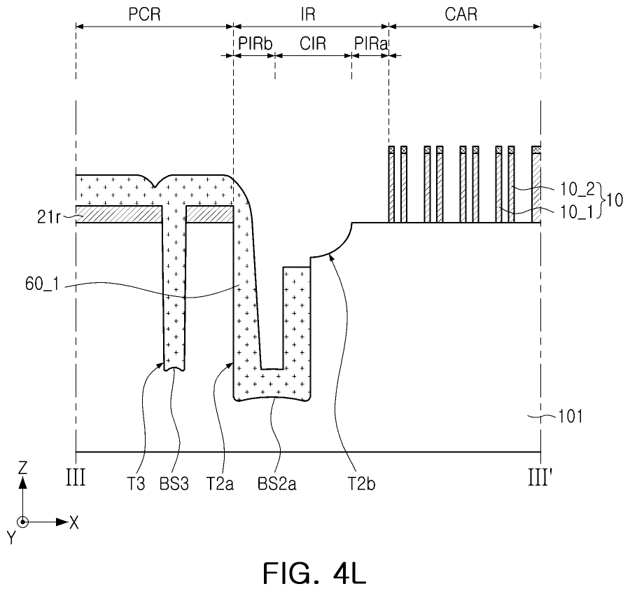

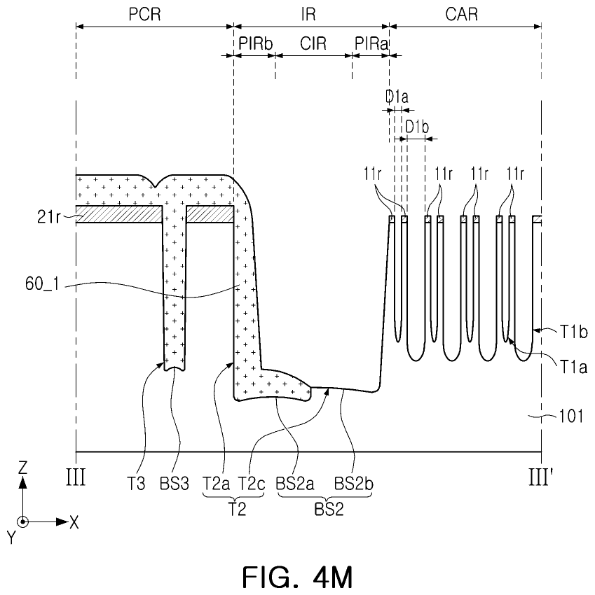

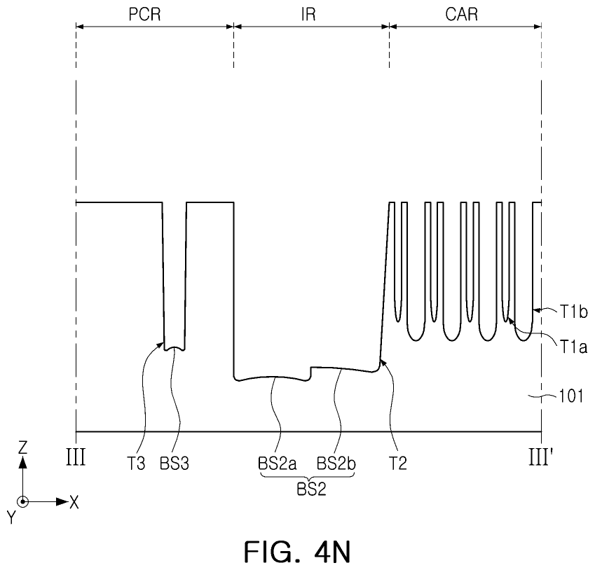

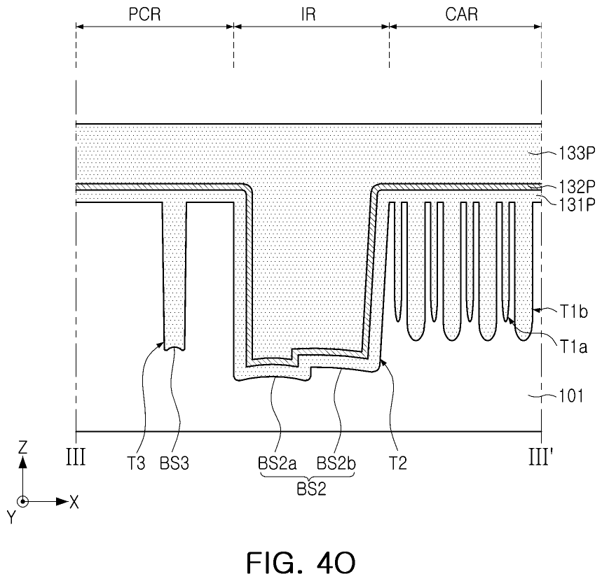

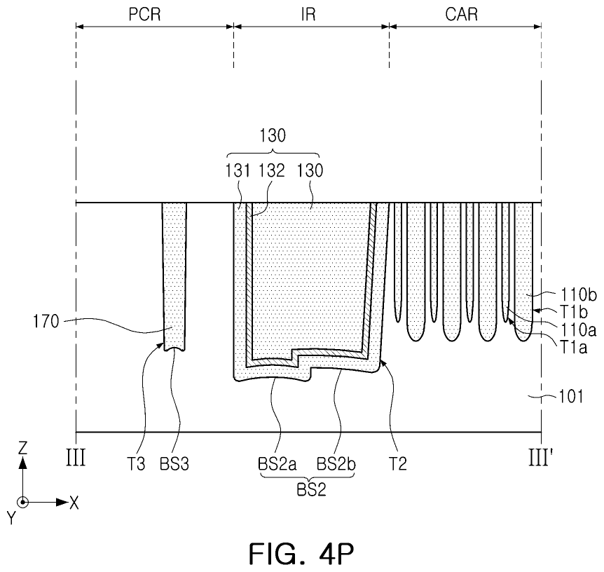

FIGS. 4A to 4P are views illustrating a method of manufacturing a semiconductor device according to an example embodiment of the present disclosure. Referring to FIGS. 4A to 4P, a method for manufacturing a semiconductor device 100 of FIG. 3A will be described.

Referring to FIG. 4A, a substrate 101 including a cell array region CAR, a peripheral circuit region PCR, and a connection region IR between the cell array region CAR and the peripheral circuit region PCR may be prepared, cell mask patterns 10 may be formed on the cell array region CAR, and peripheral mask patterns 20 may be formed on the peripheral circuit region PCR.

Each of the cell mask patterns 10 may have a bar shape extending in a diagonal direction (W-direction) of FIG. 1 from a planar perspective. In one example, the cell mask patterns 10 include first, second, third, and fourth cell mask patterns 10a, 10b, 10c and 10d, and each of the first, second, third, and fourth cell mask patterns 10a, 10b, 10c and 10d may include a 1-1 cell mask pattern 10_1 and a 1-2 cell mask pattern 10_2 spaced apart from the 1-1 cell mask pattern 10_1 in the first direction (X-direction), that is, a pair of cell mask patterns. The number of cell mask patterns 10 is illustrated as being four, but the present disclosure is not limited thereto.

Each of the 1-1 cell mask pattern 10_1 and the 1-2 cell mask pattern 10_2 may include a first cell mask layer 11 and a second cell mask layer 12 on the first cell mask layer 11.

A distance in the first direction (X-direction) between the 1-1 cell mask pattern 10_1 and the 1-2 cell mask pattern 10_2 may be a first distance D1a. A distance between the cell mask patterns 10 may be a second distance D1b. For example, a distance between a first cell mask pattern 10a and a second cell mask pattern 10b may be a second distance D1b.

The cell mask patterns 10 may define a region on which cell element separation patterns (e.g., the first and second cell element separation patterns 110a and 110b of FIG. 3A) to be described below are to be formed on the substrate 101. A space between the 1-1 cell mask pattern 10_1 and the 1-2 cell mask pattern 10_2 may define a region in which the first cell element separation pattern 110a is to be formed, and a region between the cell mask patterns 10 may define a region in which the second cell element separation pattern 110b is to be formed.

A distance between the 1 -1 cell mask pattern 10_1 and the 1-2 cell mask pattern 10_2 in the first direction (X-direction) may correspond to a horizontal width of the first cell element separation pattern 110a in the first direction (X-direction) to be described below. The distance between the cell mask patterns 10 may correspond to the horizontal width of the second cell element separation pattern 110b in the first direction (X-direction) to be described below.

Each of the 1-1 cell mask pattern 10_1 and the 1-2 cell mask pattern 10_2 may have a first horizontal width Wa in the first direction (X-direction). The first horizontal width Wa may correspond to a distance in the first direction (X-direction) between the first cell element separation pattern 110a and the second cell element separation pattern 110b to be described below.

The peripheral mask patterns 20 may define a region on the substrate 101 in which peripheral element separation patterns (e.g., peripheral element separation pattern 170 of FIG. 3A) to be described below are to be formed. In one example, the peripheral mask patterns 20 may include a first peripheral mask pattern 20a and a second peripheral mask pattern 20b spaced apart in the first direction (X-direction), but the number of peripheral mask patterns is not limited thereto.

One of the peripheral mask patterns 20 may have a second horizontal width Wb in the first direction (X-direction) of the peripheral mask pattern. The second horizontal width Wb may correspond to a distance in the first direction (X-direction) between peripheral element separation patterns 170 and the separation insulating pattern 130 described below. A distance between the peripheral mask patterns 20 may correspond to a horizontal width in the first direction (X-direction) of the peripheral element separation pattern to be described below (e.g., peripheral element separation pattern 170 of FIG. 3A).

Each of the peripheral mask patterns 20 may include a first peripheral mask layer 21 and a second peripheral mask layer 22 on the first peripheral mask layer 21.

The first cell mask layer 11 and the first peripheral mask layer 21 may include the same material. For example, the first cell mask layer 11 and the first peripheral mask layer 21 may include silicon oxide. The second cell mask layer 12 and the second peripheral mask layer 22 may include the same material. For example, the second cell mask layer 12 and the second peripheral mask layer 22 may include polycrystalline silicon.

A first opening OPN1 exposing the upper surface of the substrate 101 in the connection region IR may be formed through the cell mask patterns 10 and the peripheral mask patterns 20.

Referring to FIG. 4B, a first sacrificial layer 30 and a first mask layer 40 may be sequentially formed on the substrate 101 on the first sacrificial layer 30. The first sacrificial layer 30 may cover the cell mask patterns 10 of the cell array region CAR and the peripheral mask patterns 20 of the peripheral circuit region PCR. The first sacrificial layer 30 may be a spin on hardmask (SOH) film. The first mask layer 40 may include at least one of silicon oxide, silicon nitride, or silicon oxynitride.

Referring to FIG. 4C, a first photoresist pattern 50 including a second opening OPN2 may be formed on the first mask layer 40. An upper surface of the first mask layer 40 vertically overlapping a central region CIR of the connection region IR of the substrate 101 may be exposed through the second opening OPN2. The term “exposed,” may be used to describe relationships between elements and/or certain intermediate processes in fabricating a completed semiconductor device, but may not necessarily require exposure of the particular region, layer, structure or other element in the context of the completed device. The connection region IR may include the central region CIR and peripheral regions PIRa and PIRb surrounding the central region CIR. The peripheral regions PIRa and PIRb of the connection region IR may include a first peripheral region PIRa adjacent to the cell array region CAR and a second peripheral region PIRb adjacent to the peripheral circuit region PCR.

The first photoresist pattern 50 may be obtained from a resist film for EUV (extreme ultraviolet), a resist film for a KrF excimer laser, a resist film for an ArF excimer laser, or a resist film for an F2 excimer laser.

Referring to FIG. 4D, the first photoresist pattern 50 may be used as an etching mask to etch the first sacrificial layer 30 and the first mask layer 40, so that the central region CIR of the connection region IR of the substrate 101 may be exposed. The first sacrificial layer 30 may be separated into a first cell sacrificial layer 30_1 covering the cell mask patterns 10 and a first peripheral sacrificial layer 30_2 covering the peripheral mask patterns 20. The first mask layer 40 may be separated into a first cell mask layer 40_1 on the first cell sacrificial layer 30_1 and a first peripheral mask layer 40_2 on the first peripheral sacrificial layer 30_2. A third opening OPN3 may be formed between the first cell mask layer 40_1 and the first peripheral mask layer 40_2 and between the first cell sacrificial layer 30_1 and the first peripheral sacrificial layer 30_2. The central region CIR of the connection region IR of the substrate 101 may be exposed through the third opening OPN3.

Referring to FIG. 4E, a second mask layer 40_3 may be formed to fill the third opening OPN3 between the first cell sacrificial layer 30_1 and the first peripheral sacrificial layer 30_2 and cover the first cell mask layer 40_1 and the first peripheral mask layer 40_2. The second mask layer 40_3 may include a 2-1 mask portion 40_3a covering the central region CIR of the connection region IR of the substrate 101 and a 2-2 mask portion 40_3b extending from the 2-1 mask portion 40_3a and covering the first cell mask layer 40_1 and the first peripheral mask layer 40_2. In one example, the second mask layer 40_3 may include the same material as the first mask layer 40 of FIG. 4C. Accordingly, an interface between the first cell mask layer 40_1 and the first peripheral mask layer 40_2 of FIG. 4D and the second mask layer 40_3 may not be distinguished. However, the present disclosure is not limited thereto.

Referring to FIG. 4F, a first mask pattern 55 may be formed on the second mask layer 40_3, but the peripheral circuit region PCR and the connection region IR extending from the peripheral circuit region PCR may be exposed by the first mask pattern 55.

The first mask pattern 55 may cover the cell array region CAR, the first peripheral region PIRa of the connection region IR extending from the cell array region CAR, and a portion of the central region CIR of the connection region IR extending from the first peripheral region PIRa, and the first mask pattern 55 may expose the second mask layer 40_3 covering an upper surface and a side surface of the first peripheral sacrificial layer 30_2. The first mask pattern 55 may overlap the first cell sacrificial layer 30_1 in the vertical direction (Z-direction). From the first mask pattern 55, the peripheral circuit region PCR, the second peripheral region PIRb of the connection region IR extending from the peripheral circuit region PCR, and the remaining portion of the central region CIR may be exposed. The first mask pattern 55 may overlap the first cell sacrificial layer 30_1 and a portion of the 2-1 mask portion 40_3a in the vertical direction (Z-direction). The remaining portion of the 2-1 mask portion 40_3a may be exposed by the first mask pattern 55. The first mask pattern 55 may include the same material as the first photoresist pattern 50 of FIG. 4C.

Referring to FIG. 4G, the first mask pattern 55 may be used as an etching mask, a first etching process may be performed to form a peripheral trench T3 on a peripheral circuit region PCR, and a first auxiliary connection trench T2a may be formed on a connection region IR.

The second mask layer 40_3 exposed from the first mask pattern 55 and the first peripheral sacrificial layer 30_2 covered by the second mask layer 40_3 and covering the peripheral mask patterns 20 may be sequentially etched by the first etching process, and an upper portion of the substrate 101 may be etched so that a peripheral trench T3 on the peripheral circuit region PCR and a first auxiliary connection trench T2a on the connection region IR may be formed within the substrate 101.

A width of the peripheral trench T3 in the first direction (X-direction) on the peripheral circuit region PCR may have a third size D3. This may correspond to a distance between the peripheral mask patterns 20 of FIG. 4A. The peripheral trench T3 may have a shallower depth than the first auxiliary connection trench T2a, and the peripheral trench T3 may have a lower surface BS3 formed on a higher level than the lower region BS2a of the first auxiliary connection trench T2a, and may have a non-flat or non-planar surface having a rounded profile. The lower surface or floor BS3 of the peripheral trench T3 may have a convex surface toward the upper surface of the substrate 101.

The first auxiliary connection trench T2a on the connection area IR may have a deeper depth than the peripheral trench T3, relative to an upper surface of the substrate 101. The lower region BS2a of the first auxiliary connecting trench T2a may be disposed on a lower level than the lower surface BS3 of the surrounding trench T3 and may have a non-flat or non-planar surface with a rounded profile. The lower region BS2a of the first auxiliary connection trench T2a may have a convex surface toward the upper surface of the substrate 101.

A portion corresponding to the peripheral circuit region PCR and portions of the second peripheral region PIRb extending from the peripheral circuit region PCR and the central region CIR of the connection region IR in the second mask layer 40_3 may be removed. A portion overlapping the first mask pattern 55 in the second mask layer 40_3 may remain.

On the upper surface of the substrate 101, peripheral mask residual patterns 21r not removed in the process of removing the first peripheral mask layer 21 of FIG. 4A may remain.

Referring to FIG. 4H, a first sacrificial liner 60 may be formed on the substrate 101. The first sacrificial liner 60 may cover the second mask layer 40_3 covering a side surface and an upper surface of the first cell sacrificial layer 30_1, the peripheral trench T3 on the peripheral circuit region PCR, and the first auxiliary connection trench T2a on the connection region IR.

The first sacrificial liner 60 may be conformally formed according to surface profiles of the second mask layer 40_3, the peripheral trench T3, and the first auxiliary connection trench T2a. The first sacrificial liner 60 may include an oxide.

Referring to FIG. 4I, a second sacrificial layer 35 covering the first sacrificial liner 60 may be formed. The second sacrificial layer 35 may be a spin on hardmask (SOH) film.

Referring to FIG. 4J, a portion covering the first sacrificial liner 60 covering a side surface and an upper surface of the second mask layer 40_3 may be removed from the second sacrificial layer 35 to form a second sacrificial layer 35_1.

An upper surface of the first sacrificial liner 60 covering the side surface and the upper surface of the second mask layer 40_3 may be exposed from or by the second sacrificial layer 35_1. The first cell sacrificial layer 30_1 and the second mask layer 40_3 covering the side surface and the upper surface of the first cell sacrificial layer 30_1 may not overlap the second sacrificial layer 35_1 in the vertical direction (Z-direction). The second sacrificial layer 35_1 may overlap a portion of a first auxiliary connection trench TS2a adjacent to the peripheral circuit region PCR in the vertical direction, and may not overlap the remaining portion of the first auxiliary connection trench TS2a adjacent to the cell array region CAR in the vertical direction.

Referring to FIG. 4K, using the second sacrificial layer 35_1 as an etching mask, the first sacrificial liner 60 and the second mask layer 40_3 covering the side surface and the upper surface of the first cell sacrificial layer 30_1 may be removed, and an upper portion of the substrate 101 may be partially etched to form a second auxiliary connection trench T2b connected to the first auxiliary connection trench T2a. As the first sacrificial liner 60 covering a side surface and an upper surface of the second mask layer 40_3 is removed, a first sacrificial liner 60_1 may be disposed according to a surface profile of the peripheral trench T3 and the first auxiliary connection trench T2a, and an end of the first sacrificial liner 60_1 may be exposed through the first auxiliary connection trench T2a. In one example, the first cell sacrificial layer 30_1 covering the cell mask patterns 10 may be exposed. The substrate 101 exposed between the first sacrificial liner 60_1 and the first cell sacrificial layer 30_1 may be etched to form the second auxiliary connection trench T2b, but depending on the degree of etching, the substrate 101 exposed between the first sacrificial liner 60_1 and the first cell sacrificial layer 30_1 may not be etched.

Referring to FIG. 4L, the second sacrificial layer 35_1 and the first cell sacrificial layer 30_1 covering the cell mask patterns 10 may be removed. Accordingly, the first sacrificial liner 60_1 and the cell mask patterns 10 may be exposed.

Referring to FIG. 4M, a second etching process may be performed using the first sacrificial liner 60_1 as an etching mask to form cell trenches T1a and T1b on the cell array region CAR, and a connection trench T2 may be formed in the connection region IR.

By the second etching process, the upper portion of the substrate 101 may be etched to form cell trenches T1a and T1b on the cell array region CAR, and a connection trench T2 may be formed in the connection region IR.

The cell trenches T1a and T1b formed on the cell array region CAR may include a first cell trench T1a and a second cell trench T1b, and a horizontal width D1a of the first cell trench T1 a in the first direction (X-direction) may correspond to a distance between the 1-1 cell mask pattern 10_1 and the 1-2 cell mask pattern 10_2 of FIG. 4A, and a horizontal width D1b of the second cell trench T1b in the first direction (X-direction) may correspond to a distance between the cell mask patterns 10 of FIG. 4A. A depth of the first cell trench T1a may be shallower than a depth of the second cell trench T1b, relative to an upper surface of the substrate 101. A depth of the second cell trench T1b may be shallower than a depth of the peripheral trench T3, relative to an upper surface of the substrate 101.

The connection trench T2 formed on a connection region IR may be formed by combining a previously formed first auxiliary connection trench T2a adjacent to the peripheral circuit region PCR and covered with the first sacrificial liner 60_1 with a third auxiliary connection trench T2c adjacent to the cell array region CAR and formed by the second etching process.

A depth of the connection trench T2 may be deeper than that of each of the cell trenches T1a and T1b and may be deeper than a depth of the peripheral trench T3, relative to an upper surface of the substrate 101. The lower surface or floor BS2 of the connection trench T2 may be formed on a lower level than the lower surface BS3 of the peripheral trench T3. The lower surface BS2 of the connecting trench T2 may include a first lower region BS2a and a second lower region BS2b connected to the first lower region BS2a through a step portion but formed on a higher level than that of the first lower region BS2a. In one example, the first lower region BS2a may have a non-flat surface or non-planar surface having a rounded profile in cross-section by the first etching process, and the second lower region BS2b may have a surface in which a level thereof increases as the first lower region BS2a is closer to the first lower region BS2a by the second etching process.

On the upper surface of the substrate 101, cell mask residual patterns 11r not removed in the process of removing the first cell mask layer 11 of FIG. 4A may remain.

Referring to FIG. 4N, the first sacrificial liner 60_1, the peripheral mask residual patterns 21r, and the cell mask residual patterns 11r may be removed. After the first sacrificial liner 60_1, the peripheral mask residual patterns 21r, and the cell mask residual patterns 11r are removed, a cleaning process may be performed.

Referring to FIG. 4O, first to third insulating materials 131P, 132P and 133P may be sequentially formed on the substrate 101. The first insulating material 131P may fill the cell trenches T1a and T1b on the cell array region CAR and the peripheral trench T3 on the peripheral circuit region PCR, and may be formed conformally according to a surface profile of the connection trench T2 on the connection region IR having a relatively large horizontal width in the first direction (X-direction). The second insulating material 132P may be conformally formed on the first insulating material 131P, and the third insulating material 133P may be formed on the second insulating material 132P, e.g., to fill a remaining portion of the trench T2. The first and third insulating materials 131P and 133P may include silicon oxide, and the second insulating material 132P may include silicon nitride. The first insulating material 131P and the third insulating material 133P may be the same material, and the second insulating material 132P may be different from the first insulating material 131P and the third insulating material 133P.

Referring to FIG. 4P, a planarization process may be performed so that the upper surface of the substrate 101 is exposed. Cell element separation patterns 110a and 110b filling the cell trenches T1a and T1b may be formed on the cell array region CAR, a peripheral element separation pattern 170 filling the peripheral trench T3 may be formed on the peripheral circuit region PCR, and a separation insulating pattern 130 filling the connection trench T2 may be formed in the connection region IR. Upper surfaces of the cell element separation patterns 110a and 110b, an upper surface of the peripheral element separation pattern 170, and an upper surface of the separation insulating pattern 130 may be coplanar with each other.

Next, referring to FIG. 2B together, an operation of forming a cell gate structure WLS to intersect with portions of the cell element separation patterns 110a and 110b and the separation insulating pattern 130, an operation of forming a bit line structure BLS on the cell array region CAR, dummy structures BL_D and GS_D on the connection region IR, and a peripheral transistor on the peripheral circuit region PCR, an operation of forming a gate contact plug 160cp1 and a peripheral contact plug 160cp2, and an operation of forming a capacitor structure including a lower electrode, a capacitor dielectric layer, and an upper electrode on the first upper conductive pattern 160c, may be performed.

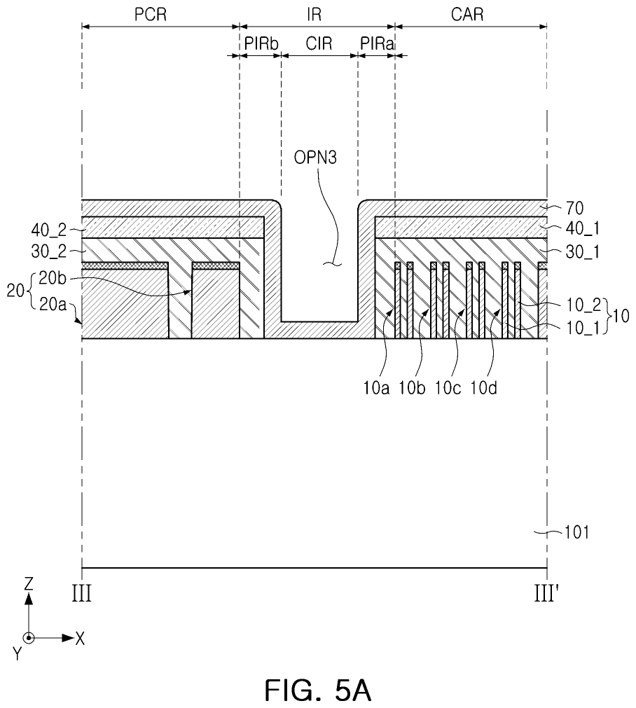

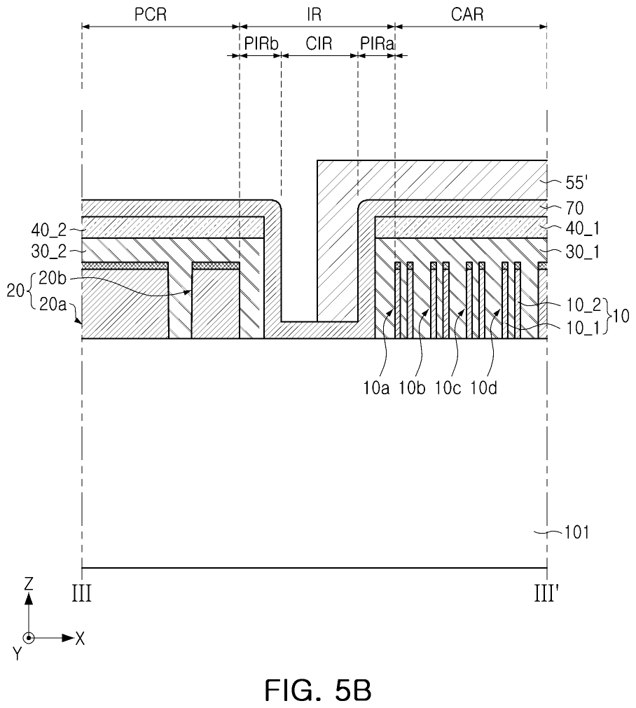

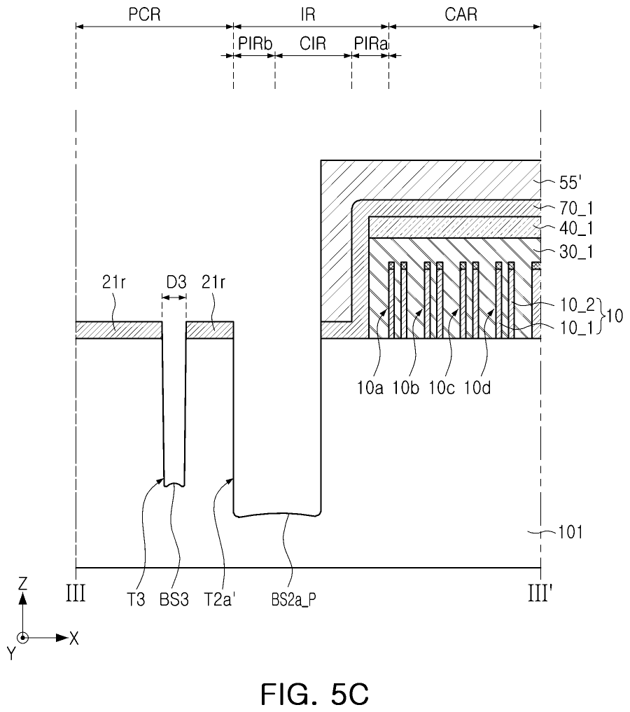

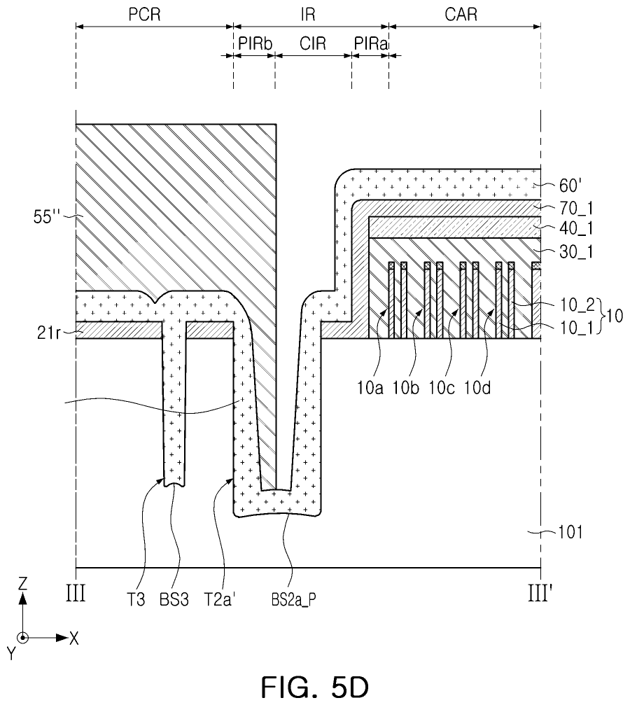

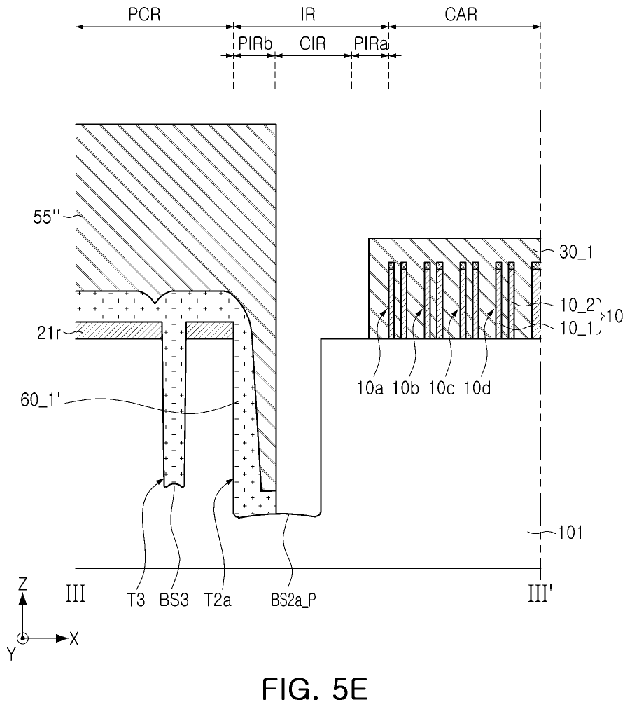

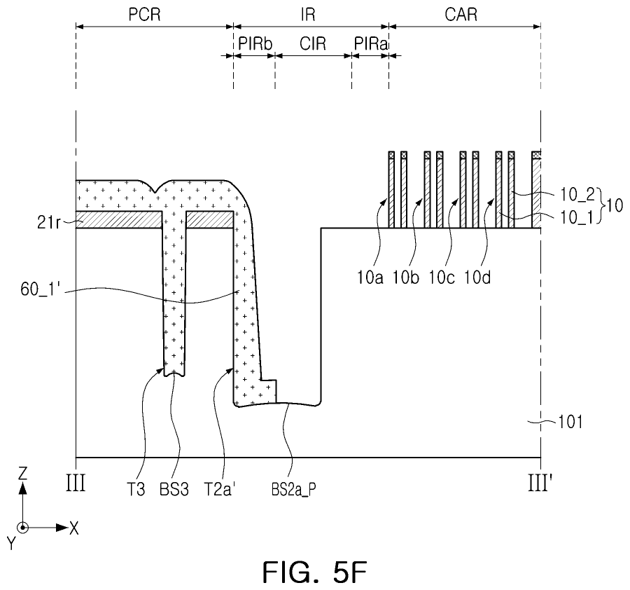

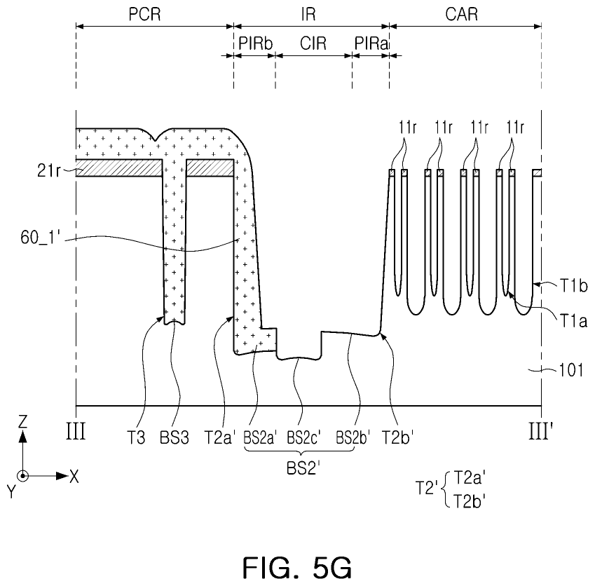

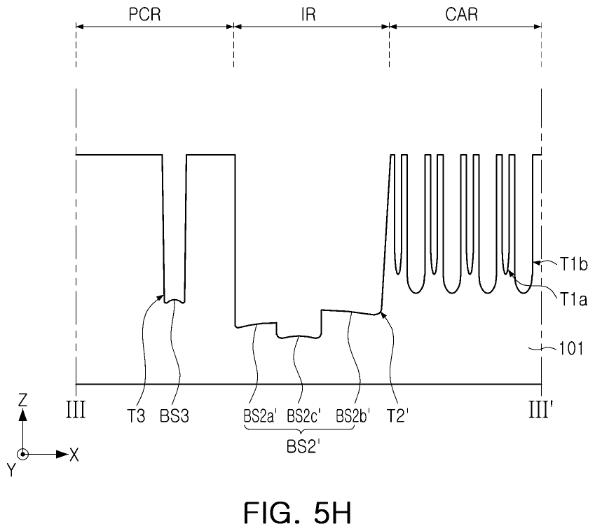

FIGS. 5A to 5H are diagrams illustrating a method of manufacturing a semiconductor device according to another example embodiment of the present disclosure. Referring to FIGS. 5A to 5H, a method for manufacturing a semiconductor device 100′ of FIG. 3B will be described.

Referring to FIG. 5A together with FIGS. 4A to 4D, a first sacrificial liner 70 covering the central region CIR of the connection region IR of the substrate 101 may be formed on the substrate 101 through the first cell mask layer 40_1, the first peripheral mask layer 40_2, and the third opening OPN3. The first sacrificial liner 70 may be conformally formed according to a surface profile of the first cell mask layer 40_1, the first peripheral mask layer 40_2, and the substrate 101. The first sacrificial liner 70 can include an oxide.

Referring to FIG. 5B, a first mask pattern 55′ covering a portion of the first sacrificial liner 70 covering the first cell sacrificial layer 30_1 and the first cell mask layer 40_1, and exposing a remaining portion of the first sacrificial liner 70 may be formed. The first mask pattern 55′ may cover the cell array region CAR and portions of the first peripheral region PIRa and the central region CIR of the connection region IR extending from the cell array region CAR. The first mask pattern 55′ may expose the peripheral circuit region PCR, the second peripheral region PIRb and remaining portions of the central region CIR of the connection region IR extending from the peripheral circuit region PCR.

Referring to FIG. 5C, a peripheral trench T3 may be formed on the peripheral circuit region PCR by utilizing the first mask pattern 55′ as an etching mask and performing a first etching process, and a first auxiliary connection trench T2a′ may be formed on the connection region IR.

The first sacrificial liner 70, the first peripheral mask layer 40_2 and the first peripheral sacrificial layer 30_2 exposed from the first mask pattern 55′ may be sequentially removed by the first etching process, and the upper portion of the substrate 101 may be etched so that within the substrate 101, a peripheral trench T3 may be formed on the peripheral circuit region PCR and a first auxiliary connection trench T2a′ may be formed on the connection region IR.

A portion exposed from the first mask pattern 55′ in the first sacrificial liner 70 may be removed, and a portion overlapping the first mask pattern 55′ and covering a side surface of the first cell sacrificial layer 30_1 and an upper surface and a side surface of the first cell mask layer 40_1 may remain, so that a first sacrificial liner 70_1 may be formed.

The first auxiliary connection trench T2a′ on the connection region IR may have a deeper depth than the peripheral trench T3, relative to a surface of the substate 101. A lower surface BS2a_P of the first auxiliary connection trench T2a′ may be disposed on a lower level than the lower surface BS3 of the peripheral trench T3 and may have a non-flat or non-planar surface having a rounded profile in cross-section. The lower surface BS2a_P of the first auxiliary connection trench T2a′ may have a convex surface toward the upper surface of the substrate 101.

On the upper surface of the substrate 101, peripheral mask residual patterns 21r not removed in the process of removing the first peripheral mask layer 21 of FIG. 4A may remain.

Referring to FIG. 5D, a second sacrificial liner 60′ may be formed on the substrate 101, and a second mask pattern 55″ covering a portion of the second sacrificial liner 60′ may be formed.

The second sacrificial liner 60′ may cover the first sacrificial liner 70_1, the peripheral trench T3 on the peripheral circuit region PCR, and the first auxiliary connection trench T2a′ on the connection region IR. The second sacrificial liner 60′ may be conformally formed according to the surface profiles of the first sacrificial liner 70_1, the peripheral trench T3, and the first auxiliary connection trench T2a′. The second sacrificial liner 60′ may include an oxide.

The first mask pattern 55′ may cover the second sacrificial liner 60′ overlapping peripheral circuit region PCR and the second peripheral region PIRb of the connection region IR adjacent to the peripheral circuit region PCR. The first mask pattern 55′ may expose the second sacrificial liner 60′ disposed on the cell array region CAR, the first peripheral region PIRa and remaining portions of the central region CIR of the connection region IR adjacent to the cell array region CAR. The first mask pattern 55′ may cover only a portion of the first auxiliary connection trench T2a′ adjacent to the peripheral circuit region PCR, and may expose a remaining portion of the first auxiliary connection trench T2a′ adjacent to the cell array region CAR.

Referring to FIG. 5E, the second sacrificial liner 60′, the first sacrificial liner 70_1 and the first cell mask layer 40_1 exposed from the second mask pattern 55′ may be removed using the second mask pattern 55′.

A portion of a side surface of the first auxiliary connection trench T2a′ and a portion of the lower surface BS2a_P of the first auxiliary connection trench T2a′ may be exposed.

The first cell sacrificial layer 30_1 covering the cell mask patterns 10 may be exposed.

A portion disposed on the first peripheral region PIRa and remaining portions of the central region CIR of the connection region IR adjacent to the cell array region CAR may be removed from the second sacrificial liner 60′, and a portion overlapping the second mask pattern 55′ may remain, so that a second sacrificial liner 60_1′ may be formed. In the first auxiliary connection trench T2a′, only a portion of the second sacrificial liner 60′ overlapping the second mask pattern 55′ may remain, and the remaining portions thereof may be removed.

The lower surface BS2a_P of the first auxiliary connection trench T2a′ may include a region covered with the second sacrificial liner 60_1′ and a region exposed from or by the second sacrificial liner 60_1′ and the second mask pattern 55′. A region covered with the second sacrificial liner 60_1′, among the lower surface BS2a_P of the first auxiliary connection trench T2a′, may correspond to the first lower region BS2a′ of the connection trench T2′ of FIG. 5G to be described below. A region exposed from the second sacrificial liner 60_1′ and the second mask pattern 55′, among the lower surface BS2a_P of the first auxiliary connecting trench T2a′, may correspond to the third lower region BS2c′ of the connecting trench T2′ described below.

Referring to FIG. 5F, the first mask pattern 55′ and the first cell sacrificial layer 30_1 may be removed. As the first mask pattern 55′ is removed, the second sacrificial liner 60_1′ may be exposed, and as the first cell sacrificial layer 30_1 is removed, the cell mask patterns 10 may be exposed.

Referring to FIG. 5G, cell trenches T1a and T1b may be formed on the cell array region CAR by utilizing the second sacrificial liner 60_1′ as an etching mask and performing a second etching process, and a connection trench T2′ may be formed in the connection region IR.

The upper surface of the substrate 101 between the first auxiliary connection trench T2a′ and the cell mask patterns 10 of FIG. 5F may be etched to form a second auxiliary connection trench T2b′ connected to the first auxiliary connection trench T2a′. The first auxiliary connection trench T2a′ and the second auxiliary connection trench T2b′ may form the connection trench T2′.

A lower surface BS2′ of the connecting trench T2′ may be disposed on a lower level than the lower surface BS3 of the peripheral trench T3. The lower surface BS2′ of the connecting trench T2′ may include a first lower region BS2a′, a second lower region B2b′, and a third lower region BS2c′ formed between the first lower region BS2a′ and the second lower region BS2b′.

The first lower region BS2a′ is a region covered with the second sacrificial liner 60_1′, and the third lower region BS2c′ may be disposed on a lower level than that of the first lower region BS2a′ by etching a region exposed from the second sacrificial liner 60_1′ and the second mask pattern 55′ in the first auxiliary connecting trench T2a′ of FIG. 5F by the second etching process. The second lower region BS2b′ may be a lower surface of the second auxiliary connection trench T2b′. The second lower region BS2b′ is a region formed by etching the upper surface of the substrate 101 between the first auxiliary connection trench T2a′ and the cell mask patterns 10 of FIG. 5F, and may be disposed on a higher level than that of the first lower region BS2a′ and the third lower region BS2c′.

The cell trenches T1a and T1b formed on the cell array region CAR may include a first cell trench T1a and a second cell trench T1b, and the horizontal width D1a of the first cell trench T1 a in the first direction (X-direction) may correspond to the distance between the 1-1 cell mask pattern 10_1 and the 1-2 cell mask pattern 10_2 of FIG. 4A, and the horizontal width D1b of the second cell trench T1b in the first direction (X-direction) may correspond to the distance between the cell mask patterns 10 of FIG. 4A. The depth of the first cell trench T1a may be shallower than the depth of the second cell trench T1b, relative to an upper surface of the substrate 101.

On the upper surface of the substrate 101, cell mask residual patterns 11r not removed in the process of removing the first cell mask layer 11 of FIG. 4A may remain.

Referring to FIG. 5H, the second sacrificial liner 60_1′, the peripheral mask residual patterns 21r and the cell mask residual patterns 11r may be removed. After removing the second sacrificial liner 60_1′, the peripheral mask residual patterns 21r and the cell mask residual patterns 11r, a cleaning process may be performed.

The process operations described with reference to FIG. 4O may be applied in the same manner to the subsequent process operations, to form the semiconductor device 100′ shown in FIG. 3B.

A method for manufacturing a semiconductor device according to example embodiments of the present disclosure may include preparing a substrate having a cell array region, a peripheral circuit region, and a connection region between the cell array region and the peripheral circuit region; forming peripheral trenches in the peripheral circuit region and a first auxiliary connection trench in the connection region adjacent to the peripheral circuit region; forming a second auxiliary connection trench in the connection region extending from the first auxiliary connection trench; and forming cell trenches in the cell array region and a connection trench in the connection region adjacent to the cell array region.

In one embodiment, the method for manufacturing a semiconductor device may further include forming a first sacrificial layer exposing an upper surface of a central region of the connection region surrounded by a peripheral region of the connection region; and forming a first mask layer covering the upper surface of the central region of the connection region and the first sacrificial layer.

In one embodiment, forming the peripheral trenches and the first auxiliary connection trench may comprise forming a first mask pattern on the first sacrificial layer exposing the peripheral circuit region and a portion of the connection region extending from the peripheral circuit region; and performing a first etching process on the substrate using the first mask pattern.

In one embodiment, forming the second auxiliary connection trench connected to the first auxiliary connection trench may comprise forming a first sacrificial liner covering the first mask layer, the peripheral trenches, and the first auxiliary connection trench, the first mask layer extends from the cell array region to cover a portion of the central region of the connection region; forming a second sacrificial layer on the first sacrificial liner such that an upper surface of the first sacrificial liner formed on the first mask layer is exposed; and removing the exposed first sacrificial liner and the first mask pattern from the second sacrificial layer to expose the first sacrificial layer.

In one embodiment, forming the cell trenches and the connection trench may comprise removing the first sacrificial layer and the second sacrificial layer; and performing a second etching process on the substrate using the first sacrificial liner.

In one embodiment, the first sacrificial liner may be conformally formed along surface profiles of the first mask layer, the peripheral trenches, and the first auxiliary connection trench.

In one embodiment, the method for manufacturing a semiconductor device may further include forming cell mask patterns on the cell array region and forming peripheral mask patterns on the peripheral circuit region. each of the cell mask patterns comprises a first cell mask pattern and a second cell mask pattern spaced apart from the first cell mask pattern by a first size.

In one embodiment, the peripheral mask patterns have a second size that is greater than the first size between adjacent the cell mask patterns.

In one embodiment, the peripheral mask patterns have a third size greater than the second size.

In one embodiment, forming the cell trenches in the cell array region may comprise forming a first cell trench between the first cell mask pattern and the second cell mask pattern; and forming second cell trenches between the cell mask patterns.

In one embodiment, a width of the peripheral trench in a first direction may be smaller than a width of the first auxiliary connection trench in the first direction.

While example embodiments have been illustrated and described above, it will be apparent to those skilled in the art that modifications and variations could be made without departing from the concept and the scope of the present disclosure as defined by the appended claims.

What is claimed is:

1. A semiconductor device, comprising:
a substrate comprising a cell array region, a peripheral circuit region, and a connection region between the cell array region and the peripheral circuit region;
a cell element separation pattern defining a cell active region on the cell array region, on the substrate;
a peripheral element separation pattern defining a peripheral active region on the peripheral circuit region, on the substrate;
a separation insulating pattern between the cell element separation pattern and the peripheral element separation pattern on the connection region, of the substrate; and
a cell gate structure intersecting the cell active region and extending into the separation insulating pattern,
wherein a lower surface of the separation insulating pattern comprises a first lower region adjacent to the peripheral circuit region and on a first level, a second lower region adjacent to the cell array region and on a second level that is higher than the first level relative to an upper surface of the substrate, and a first step portion between the first lower region and the second lower region.

2. The semiconductor device of claim 1,
wherein the first lower region comprises a non-planar surface having a rounded profile in cross-section, and
wherein the second lower region comprises a surface that is inclined toward the first lower region.

3. The semiconductor device of claim 2,
wherein, in cross section, the first lower region has a convex surface profile toward the upper surface of the substrate.

4. The semiconductor device of claim 1,
wherein the cell active region extends in a first direction parallel to the upper surface of the substrate, and
the cell gate structure extends in a second direction parallel to the upper surface of the substrate and intersecting the first direction,
wherein the semiconductor device further includes a bit line structure extending in a third direction parallel to the upper surface of the substrate and intersecting the first direction and the second direction.

5. The semiconductor device of claim 1, further comprising:
a cell gate contact plug connected to the cell gate structure on the connection region,
wherein the cell gate contact plug overlaps the separation insulating pattern in a direction perpendicular to the upper surface of the substrate.

6. The semiconductor device of claim 1,
wherein the lower surface of the separation insulating pattern further comprises:
a third lower region between the first lower region and the second lower region and on a third level that is lower than the first level relative to the upper surface of the substrate, and a second step portion between the second lower region and the third lower region.

7. The semiconductor device of claim 6,
wherein the third lower region has a non-planar surface having a rounded profile in cross-section, and
wherein the first lower region and the second lower region comprise surfaces that are inclined toward the third lower region.

8. The semiconductor device of claim 1,
wherein the cell gate structure comprises a gate dielectric layer, a gate electrode on the gate dielectric layer, and a gate capping layer on the gate electrode, and
wherein a side surface of the gate dielectric layer is in contact with the separation insulating pattern.

9. The semiconductor device of claim 1,
wherein the separation insulating pattern comprises a first insulating layer conformally extending along a surface profile, a second insulating layer on the first insulating layer, and a third insulating layer on the second insulating layer,
wherein the first insulating layer and the third insulating layer comprise a first insulating material, and
wherein the second insulating layer comprises a second insulating material that is different from the first insulating material.

10. The semiconductor device of claim 9,
wherein the cell element separation pattern and the peripheral element separation pattern comprise the first insulating material.

11. The semiconductor device of claim 1,
wherein the cell element separation pattern comprises a first cell separation pattern having a first depth and a second cell separation pattern having a second depth that is greater than the first depth, relative to the upper surface of the substrate, and
a width of the second cell separation pattern in a first direction is greater than a width of the first cell separation pattern in the first direction.

12. The semiconductor device of claim 11,
wherein a width of the peripheral element separation pattern in the first direction is greater than the width of the second cell separation pattern in the first direction.

13. A semiconductor device, comprising:
a substrate comprising a cell array region, a peripheral circuit region, and a connection region between the cell array region and the peripheral circuit region;
a cell element separation pattern defining a cell active region on the cell array region, on the substrate;
a peripheral element separation pattern defining a peripheral active region on the peripheral circuit region, on the substrate;
a separation insulating pattern between the cell element separation pattern and the peripheral element separation pattern on the connection region of the substrate; and
a cell gate structure intersecting the cell active region and extending into the separation insulating pattern,
wherein a lower surface of the separation insulating pattern comprises a first lower region on a first level, a second lower region on a second level that is higher than the first level relative to an upper surface of the substrate, and a first step portion between the first lower region and the second lower region,
wherein the first lower region comprises a non-planar surface having a rounded profile in cross-section, and
wherein the second lower region comprises a surface that is inclined toward the first lower region.

14. The semiconductor device of claim 13,
wherein the first lower region is adjacent to the peripheral circuit region, and
wherein the second lower region is adjacent to the cell array region.

15. The semiconductor device of claim 13,
wherein the lower surface of the separation insulating pattern further comprises:
a third lower region on a third level that is higher than the first level of the first lower region and lower than the second level of the second lower region, relative to the upper surface of the substrate; and
a second step portion between the first lower region and the third lower region, and
wherein the third lower region comprises a surface that is inclined toward the first lower region.

16. The semiconductor device of claim 15,
wherein the first lower region is between the third lower region and the second lower region,
wherein the third lower region is adjacent to the peripheral element separation pattern, and
wherein the second lower region is adjacent to the cell element separation pattern.

17. The semiconductor device of claim 15, further comprising:
a cell gate contact plug connected to the cell gate structure on the connection region,
wherein the cell gate contact plug overlaps the separation insulating pattern in a direction perpendicular to the upper surface of the substrate.

18. The semiconductor device of claim 13,
wherein the separation insulating pattern comprises a first insulating layer conformally extending along a surface profile, a second insulating layer on the first insulating layer, and a third insulating layer on the second insulating layer,
wherein the first insulating layer and the third insulating layer comprise a first insulating material,
wherein the second insulating layer comprises a second insulating material that is different from the first insulating material, and
wherein the cell element separation pattern and the peripheral element separation pattern comprise the first insulating material.

19. The semiconductor device of claim 13,
wherein the peripheral element separation pattern comprises a lower surface having a greater depth than the cell element separation pattern, relative to the upper surface of the substrate, and
wherein the lower surface of the peripheral element separation pattern has a convex surface profile toward the upper surface of the substrate.

20. A semiconductor device, comprising:
a substrate comprising a cell array region, a peripheral circuit region, and a connection region between the cell array region and the peripheral circuit region;
a cell element separation pattern defining cell active regions on the cell array region, on the substrate;
a peripheral element separation pattern defining peripheral active regions on the peripheral circuit region, on the substrate;
a separation insulating pattern on the connection region on the substrate;
a cell gate structure intersecting the cell active regions and extending into a portion of the separation insulating pattern;
a bit line structure intersecting the cell active regions and the cell gate structure; and
a cell gate contact plug connected to the cell gate structure on the connection region and overlapping the separation insulating pattern in a direction perpendicular to an upper surface of the substrate,
wherein the cell element separation pattern comprises a first cell separation pattern having a first depth and a second cell separation pattern having a second depth that is greater than the first depth, relative to the upper surface of the substrate,
the separation insulating pattern has a lower surface on a lower level than the cell element separation pattern and the peripheral element separation pattern, relative to the upper surface of the substrate, and
the lower surface of the separation insulating pattern comprises a first lower region adjacent to the peripheral circuit region and on a first level, a second lower region adjacent to the cell array region and on a second level that is higher than the first level relative to the upper surface of the substrate, and a step portion between the first lower region and the second lower region.
